(19) United States
(12) Patent Application Publication
(10) Pub. No.: US 2021/0050538 A1
(43) Pub. Date: Feb. 18, 2021

(54) METHOD AND SYSTEM FOR COLOR NEUTRAL TRANSPARENT PHOTOVOLTAICS

(71) Applicant: Ubiquitous Energy, Inc., REDWOOD CITY, CA (US)

(72) Inventors: Richa Pandey, Sunnyvale, CA (US); Miles C. Barr, Redwood City, CA (US); Matthew E. Sykes, Redwood City, CA (US); John A. Love, Mountain View, CA (US)

(73) Assignee: Ubiquitous Energy, Inc., REDWOOD CITY, CA (US)

(21) Appl. No.: 16/994,369

(22) Filed: Aug. 14, 2020

Related U.S. Application Data
(60) Provisional application No. 62/887,942, filed on Aug. 16, 2019.

(51) Int. Cl. H01L 51/42; H01L 51/44

(52) U.S. Cl. CPC H01L 51/4253; H02S 20/26; H01L 51/442

(57) ABSTRACT

Disclosed herein are visibly transparent photovoltaic devices, such as color-neutral visibly transparent photovoltaic devices. A color-neutral visibly transparent photovoltaic device includes a visibly transparent substrate and a first visibly transparent electrode coupled to the visibly transparent substrate. The device also includes a second visibly transparent electrode and a visibly transparent photoactive layer between the first visibly transparent electrode and the second visibly transparent electrode. The visibly transparent photoactive layer is configured to convert at least one of NIR light or UV light into photocurrent and is characterized by an absorption spectrum with a peak in the NIR or UV spectrum. The device further includes a visibly absorbing material characterized by a second absorption spectrum with a second peak in the visible spectrum, where the second absorption spectrum is complementary to the absorption spectrum.

### CROSS-REFERENCES TO RELATED APPLICATIONS

This application claims the benefit of priority to U.S. Provisional Patent Application No. 62/887,942, filed Aug. 16, 2019, entitled “METHOD AND SYSTEM FOR COLOR NEUTRAL TRANSPARENT PHOTOVOLTAICS,” the entire content of which is incorporated herein by reference for all purposes.

### BACKGROUND OF THE INVENTION

Low-cost, visibly transparent or semitransparent organic photovoltaic (OPV) devices that can be integrated into window panes in homes, skyscrapers, automobiles, and the like, may be used to significantly increase the surface area for solar energy harvesting. For example, building-integrated photovoltaic (PV) technologies can be used to convert solar energy irradiated onto buildings into electrical energy that can be used or stored at the building or can be fed back to the power grid and to reduce heating of the building by solar energy. However, such PV technologies have not been widely used due to, for example, the cost, opacity, and aesthetic issues associated with traditional PV cells.

### SUMMARY OF THE INVENTION

This application relates generally to the field of photovoltaic materials and devices, and, more particularly, to visibly transparent (or semitransparent) photovoltaic materials and devices that have color-neutral visible light transmissivity.

Techniques disclosed herein relate generally to photovoltaic materials and devices, such as transparent or semitransparent photovoltaic materials and devices. More particularly, and without limitation, disclosed herein are combinations of materials for color-neutral visibly transparent (or semitransparent) photovoltaics, and color-neutral visibly transparent photovoltaic devices and systems incorporating combinations of materials. Various inventive embodiments are described herein, including materials, combinations of materials, devices, systems, modules, methods, and the like.

A summary of the present invention is provided below in reference to a list of examples. As used below, any reference to a series of examples is to be understood as a reference to each of those examples disjunctively (e.g., “Examples 1-4” is to be understood as “Examples 1, 2, 3, or 4”).

Example 1 is a visibly transparent photovoltaic device comprising: a visibly transparent substrate; a first visibly transparent electrode coupled to the visibly transparent substrate; a second visibly transparent electrode; a visibly transparent photoactive layer between the first visibly transparent electrode and the second visibly transparent electrode, the visibly transparent photoactive layer configured to convert at least one of near-infrared (NIR) light or ultraviolet (UV) light into photocurrent and characterized by an absorption spectrum with a peak in the NIR or UV spectrum; and a visibly absorbing material characterized by a second absorption spectrum with a second peak in the visible spectrum, wherein the second absorption spectrum is complementary to the absorption spectrum.

Example 2 is the visibly transparent photovoltaic device of example(s) 1, wherein the visibly transparent photovoltaic device is characterized by a flat transmission profile across the visible spectrum, having an absolute variation in transmission percentage of less than 30% between the wavelengths of 450 nm and 650 nm.

Example 3 is the visibly transparent photovoltaic device of example(s) 2, wherein the absolute variation in transmission percentage is less than 10%.

Example 4 is the visibly transparent photovoltaic device of example(s) 1, wherein the visibly transparent photovoltaic device is characterized by transmitted a* and b* values between −10 and 10 in International Commission on Illumination (CIE) L*a*b* (CIELAB) color space.

Example 5 is the visibly transparent photovoltaic device of example(s) 4, wherein the visibly transparent photovoltaic device is characterized by the transmitted a* and b* values between −5 and 5 in the CIELAB color space.

Example 6 is the visibly transparent photovoltaic device of example(s) 1, wherein the visibly transparent photovoltaic device is characterized by negative transmitted a* and negative transmitted b* values in the International Commission on Illumination (CIE) L*a*b* (CIELAB) color space.

Example 7 is the visibly transparent photovoltaic device of example(s) 1, wherein the visibly transparent photovoltaic device is characterized by an average visible transmission (AVT) greater than 40%.

Example 8 is the visibly transparent photovoltaic device of example(s) 1, wherein the visibly transparent photoactive layer includes a donor material and an acceptor material.

Example 9 is the visibly transparent photovoltaic device of example(s) 1, wherein the visibly absorbing material is included in the visibly transparent photoactive layer.

Example 10 is the visibly transparent photovoltaic device of example(s) 1, wherein the visibly absorbing material is included in an optical layer of the visibly transparent photovoltaic device.

Example 11 is the visibly transparent photovoltaic device of example(s) 1, wherein the visibly absorbing material is blended with the photoactive layers in a ternary or quaternary blend.

Example 12 is the visibly transparent photovoltaic device of example(s) 1, wherein the visibly absorbing material is disposed between the first electrode and the photoactive layers.

Example 13 is the visibly transparent photovoltaic device of example(s) 1, wherein the visibly absorbing material is disposed between the photoactive layers and the second electrode.

Example 14 is the visibly transparent photovoltaic device of example(s) 1, wherein the visibly absorbing material is disposed above the second electrode.

Example 15 is the visibly transparent photovoltaic device of example(s) 1, further comprising a second visibly absorbing material characterized by a third absorption spectrum with a third peak in the visible spectrum, wherein the third absorption spectrum is complementary to the absorption spectrum and the second absorption spectrum, wherein the first visibly absorbing material is disposed between the first electrode and the photoactive layers and the second visibly absorbing material is disposed between the photoactive layers and the second electrode.

Example 16 is the visibly transparent photovoltaic device of example(s) 1, further comprising a second visibly absorbing material characterized by a third absorption spectrum with a third peak in the visible spectrum, wherein the third absorption spectrum is complementary to the absorption spectrum and the second absorption spectrum, wherein the first visibly absorbing material is disposed between the first electrode and the second electrode and the second visibly absorbing material is disposed above the second electrode.

Example 17 is the visibly transparent photovoltaic device of example(s) 1, wherein the visibly absorbing material is included in a photoactive binary, ternary, or quaternary blend disposed between the first visibly transparent electrode and the second visibly transparent electrode.

Example 18 is a method of manufacturing a visibly transparent photovoltaic device, the method comprising: providing a visibly transparent substrate; forming a first visibly transparent electrode coupled to the visibly transparent substrate; forming a second visibly transparent electrode; forming a visibly transparent photoactive layer between the first visibly transparent electrode and the second visibly transparent electrode, the visibly transparent photoactive layer configured to convert at least one of near-infrared (NIR) light or ultraviolet (UV) light into photocurrent and characterized by an absorption spectrum with a peak in the NIR or UV spectrum; and incorporating a visibly absorbing material characterized by a second absorption spectrum with a second peak in the visible spectrum, wherein the second absorption spectrum is complementary to the absorption spectrum.

Example 19 is the method of example(s) 18, wherein the visibly transparent photovoltaic device is characterized by a flat transmission profile across the visible spectrum, having an absolute variation in transmission percentage of less than 30% between the wavelengths of 450 nm and 650 nm.

Example 20 is the method of example(s) 19, wherein the absolute variation in transmission percentage is less than 10%.

Example 21 is the method of example(s) 18, wherein the visibly transparent photovoltaic device is characterized by transmitted a* and b* values between −10 and 10 in International Commission on Illumination (CIE) L*a*b* (CIELAB) color space.

Example 22 is the method of example(s) 21, wherein the visibly transparent photovoltaic device is characterized by the transmitted a* and b* values between −5 and 5 in the CIELAB color space.

Example 23 is the method of example(s) 18, wherein the visibly transparent photovoltaic device is characterized by negative transmitted a* and negative transmitted b* values in in the International Commission on Illumination (CIE) L*a*b* (CIELAB) color space.

Example 24 is the method of example(s) 18, wherein the visibly transparent photovoltaic device is characterized by an average visible transmission greater than 25%.

Example 25 is the method of example(s) 18, wherein the visibly transparent photoactive layer includes a donor material and an acceptor material.

Example 26 is the method of example(s) 18, wherein the visibly absorbing material is included in the visibly transparent photoactive layer.

Example 27 is the method of example(s) 18, wherein the visibly absorbing material is included in an optical layer of the visibly transparent photovoltaic device.

Example 28 is the visibly transparent photovoltaic device of example(s) 8, wherein: a highest occupied molecular orbital (HOMO) level of the donor material is higher than or equal to a HOMO level of the acceptor material; and a lowest unoccupied molecular orbital (LUMO) level of the donor material is higher than or equal to a LUMO level of the acceptor material.

Example 29 is the visibly transparent photovoltaic device of example(s) 8, wherein the visibly absorbing material is adjacent to the donor material and is characterized by a HOMO level higher than or equal to a HOMO level of the donor material.

Example 30 is the visibly transparent photovoltaic device of example(s) 29, wherein the visibly absorbing material is characterized by a LUMO level lower than a LUMO level of the donor material.

Example 31 is the visibly transparent photovoltaic device of example(s) 8, wherein the visibly absorbing material is adjacent to the acceptor material and is characterized by a LUMO level lower than or equal to a LUMO level of the acceptor material.

Example 32 is the visibly transparent photovoltaic device of example(s) 31, wherein the visibly absorbing material is characterized by a HOMO level higher than a HOMO level of the acceptor material.

Example 33 is the visibly transparent photovoltaic device of example(s) 31, further comprising a second visibly absorbing material that is adjacent to the donor material and is characterized by a HOMO level higher than or equal to a HOMO level of the donor material.

Example 34 is the visibly transparent photovoltaic device of example(s) 8, wherein the donor material and the acceptor material are mixed in a same layer.

Example 35 is the visibly transparent photovoltaic device of example(s) 34, wherein the visibly absorbing material is characterized by a HOMO level higher than or equal to a HOMO level of the donor material.

Example 36 is the visibly transparent photovoltaic device of example(s) 35, wherein the visibly absorbing material is characterized by a LUMO level higher than a LUMO level of the acceptor material.

Example 37 is the visibly transparent photovoltaic device of example(s) 34, wherein the visibly absorbing material is characterized by a LUMO level lower than or equal to a LUMO level of the acceptor material.

Example 38 is the visibly transparent photovoltaic device of example(s) 37, wherein the visibly absorbing material is characterized by a HOMO level lower than a HOMO level of the donor material.

Example 39 is the visibly transparent photovoltaic device of example(s) 37, further comprising a second visibly absorbing material that is characterized by a HOMO level higher than a HOMO level of the donor material.

Numerous benefits are achieved using techniques described in the present disclosure over conventional techniques. Embodiments in the present disclosure provide combinations of materials and devices for absorbing near-infrared and/or ultraviolet radiation for photovoltaic power generation while being approximately uniformly transparent or semitransparent to visible light. Advantageously, these optical characteristics provide for the ability to generate electricity from incident solar radiation in a photovoltaic device, while still allowing visible light to pass through approximately uniformly and permitting a viewer to see through the photovoltaic device without or with reduced color distortion.

More specifically, the combinations of the materials include photoactive compounds that provide suitable electron donors and/or acceptors for separation of electron-hole pairs via absorption of light in order to provide a DC voltage and current to an external circuit. Advantageously, the disclosed combinations of photoactive materials include those that are transparent to visible light or only absorb relatively small amounts of light in the visible band, such as between about 450 and about 650 nm, while exhibiting a greater absorption strength in the near-infrared (NIR) band, such as between about 650 nm and about 1400 nm, or the ultraviolet (UV) band, such as between about 280 nm and about 450 nm.

Furthermore, the combinations of materials may include materials that have visible light absorptivity complementary to the combined visible light absorptivity of the materials for NIR and/or UV light absorption. As such, the combinations of materials may have a substantially uniform absorptivity (and hence uniform transmissivity) in the visible band. Therefore, the transparent or semitransparent photovoltaic devices including the combinations of materials may be seen as transparent with gray color such that the aesthetics of the building on which the photovoltaic devices are mounted may not be affected. Moreover, the transparent or semitransparent photovoltaic devices may not distort the colors of objects viewed by a person through the transparent or semitransparent photovoltaic devices.

The disclosed combinations of organic photoactive materials may also provide advantages with respect to the fabrication and performance of visibly transparent photovoltaic devices. For example, in some embodiments, the devices including the organic transparent photoactive materials described herein may be manufactured using techniques in which the organic photoactive materials are formed on a substrate using vacuum deposition techniques. Use of vacuum deposition techniques may allow high purity photoactive layers to be formed, thus improving device efficiency and performance and reducing manufacturing complexity. Transparent photovoltaic devices may incorporate the disclosed photoactive materials into active material layers by way of vacuum thermal evaporation techniques or by solution processing steps. Further, in some embodiments, the disclosed photoactive materials may be purified by an evaporation and/or sublimation technique. Purification by evaporation and/or sublimation may be useful for generating high purity photoactive materials and compounds, which may, in turn, allow improved transparent photovoltaic device production and performance.

These and other embodiments and aspects of the invention along with many of its advantages and features are described in more detail in conjunction with the text below and attached figures.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1A is a simplified diagram illustrating an example of a visibly transparent photovoltaic device that is color neutral in the visible band according to certain embodiments.

FIG. 1B illustrates various configurations of photoactive layer(s) in visibly transparent photovoltaic devices according to certain embodiments.

FIG. 2 is simplified plot illustrating the solar spectrum, human eye sensitivity, and the absorption spectrum of an example of a transparent photovoltaic device as a function of light wavelength.

FIG. 3 is a simplified energy level diagram of an example of a visibly transparent photovoltaic device according to certain embodiments.

FIGS. 4A-4H illustrate absorption profiles of examples of photoactive layers with different electron acceptor and donor configurations.

FIG. 5 illustrates the International Commission on Illumination (CIE) L*a*b* (CIELAB) color space for describing colors.

FIG. 6 illustrates transmission spectra of examples of materials used in organic photovoltaic (OPV) devices.

FIG. 7 is a simplified plot illustrating transmission spectra for an example of a transparent photovoltaic (TPV), an example of a complementary visibly absorbing material, and a combination of the TPV material with the visibly absorbing material in a device to create a color-neutral TPV according to certain embodiments.

FIG. 8 illustrates an example of a transmission spectrum for a color-neutral visibly transparent photovoltaic device according to certain embodiments.

FIG. 9 illustrates examples of absorption spectra of materials in an example of a color-neutral visibly transparent photovoltaic device according to certain embodiments.

FIG. 10 illustrates absorption spectra of examples of TPV materials and examples of visibly absorbing materials in a color-neutral visibly transparent photovoltaic device according to certain embodiments.

FIGS. 11A-11H illustrate device configurations and energy level alignments of some examples of color-neutral visibly transparent photovoltaic devices according to certain embodiments.

FIGS. 12A-12J illustrate device configurations and energy level alignments of some examples of color-neutral visibly transparent photovoltaic devices according to certain embodiments.

FIGS. 13A-13B illustrate the device configuration and energy level alignment of an example of a color-neutral visibly transparent photovoltaic device according to certain embodiments.

FIG. 14 illustrates an example of a color-neutral visibly transparent photovoltaic device including a visible light absorption optical layer according to certain embodiments.

FIG. 15 illustrates simulated transmission spectra of examples of color-neutral visibly transparent photovoltaic devices including a visible light absorption optical layer having different thicknesses according to certain embodiments.

FIG. 16 illustrates examples of color coordinates of visible light transmitted through examples of color-neutral visibly transparent photovoltaic devices including a visible light absorption optical layer having different thicknesses according to certain embodiments.

FIG. 17 illustrates an experimentally measured transmission spectrum of an example of a color-neutral visibly transparent photovoltaic device according to certain embodiments.

FIG. 18 illustrates an example of a method for manufacturing a color-neutral visibly transparent photovoltaic device according to certain embodiments.

FIG. 19 illustrates a method for making a visibly transparent photovoltaic device.

The figures depict embodiments of the present disclosure for purposes of illustration only. For example, the transmission or absorption spectra in some figures are for illustration purposes only and may not represent the transmission or absorption spectrum of a material used in an actual TPV device. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF SPECIFIC EMBODIMENTS

The present disclosure relates generally to photovoltaic materials and devices, such as transparent or semitransparent photovoltaic materials and devices. More particularly, and without limitation, disclosed herein are materials or combinations of materials for color-neutral visibly transparent (or semitransparent) photovoltaics, and color-neutral visibly transparent photovoltaic devices and systems incorporating the materials or combinations of materials. The color-neutral visibly transparent photoactive materials combinations preferentially absorb light in the near-infrared and/or ultraviolet bands and approximately uniformly transmit light in the visible band, such that the transparent photovoltaic device is color-neutral in the visible band. For example, the color-neutral visibly transparent photovoltaic materials may include photoactive materials that may more strongly absorb light in the near-infrared (NIR) band or ultraviolet (UV) band and may absorb some visible light, and may also include one or more photoactive or passive materials that have a combined visible light absorptivity complementary to a combined visible light absorptivity of the NIR and/or UV light absorption active materials. In some embodiments, the combination of materials may have any desirable transmissivity in the visible band.

Traditional photovoltaic devices, such as crystalline silicon photovoltaic devices, are generally opaque to visible light, and thus may not be suitable for use in window panes of buildings or other structures. Some transparent photovoltaic devices, such as some organic transparent photoactive material-based transparent photovoltaic devices, may be transparent or semitransparent to visible light. However, these transparent photovoltaic devices may have a structured absorption (or transmission) spectra in the visible band, and thus may show certain colors, such as certain shades of magenta, yellow, green, or blue, and may change the color of the building or colors of the objects viewed by a person through the transparent photovoltaic devices.

According to certain embodiments, various combinations of transparent or semitransparent photoactive and/or passive materials are used in a transparent photovoltaic (TPV) device to achieve color-neutral transmissivity in the visible band. In some embodiments, the neutral color of the TPV devices may be achieved using active materials with no or very low visible light absorption. In some embodiments, the neutral color of the TPV devices may be achieved using visible light absorption materials (i.e., visibly absorbing materials) with visible band absorption spectra complementary to the visible band absorption spectra of photoactive layers for UV and/or NIR light absorption, such that a substantially flat transmissivity in the visible band may be achieved, which may lead to a neutral color. The visibly absorbing materials may or may not contribute to photocurrent production and may slightly reduce average visible transmittance (AVT).

Numerous benefits can be achieved using techniques described in the present disclosure over conventional techniques. For example, embodiments in the present disclosure provide combinations of materials and devices for absorbing near-infrared and/or ultraviolet radiation for photovoltaic power generation while being approximately uniformly transparent or semitransparent to visible light. Advantageously, these optical characteristics provide for the ability to generate electricity from incident solar radiation in a photovoltaic device, while still allowing visible light to pass through approximately uniformly and permitting a viewer to see through the photovoltaic device with minimal color distortion.

Techniques disclosed herein can be used to combine different materials to make photovoltaic layers and devices that have any desired transmission or absorption characteristics in the visible band, including color-neutral transmission or preferential absorption in certain wavelengths or colors (e.g., higher absorption at red or blue wavelengths).

In general, the terms and phrases used herein have their art-recognized meaning, which can be found by reference to standard texts, journal references, and contexts known to those skilled in the art. The following definitions are provided to clarify their specific use in the context of the present disclosure.

As used herein, the term “visible light” may refer to light within a wavelength range from about 380 nm to about 750 nm, from about 400 nm to about 700 nm, or from about 450 nm to about 650 nm.

As used herein, the terms “visibly transparent” (or simply “transparent”) and “visibly semitransparent” (or simply “semitransparent”), and the like, may refer to a character of a material or device that exhibits an overall absorption, average absorption, or maximum absorption in the visible band within about 0%-70%, such as less than or about 70%, less than or about 65%, less than or about 60%, less than or about 55%, less than or about 50%, less than or about 45%, less than or about 40%, less than or about 35%, less than or about 30%, less than or about 25%, or less than or about 20%. Stated another way, visibly transparent materials may transmit 30%-100% of incident visible light, such as greater than or about 80% of incident visible light, greater than or about 75% of incident visible light, greater than or about 70% of incident visible light, greater than or about 65% of incident visible light, greater than or about 60% of incident visible light, greater than or about 55% of incident visible light, greater than or about 50% of incident visible light, greater than or about 45% of incident visible light, greater than or about 40% of incident visible light, greater than or about 35% of incident visible light, or greater than or about 30% of incident visible light. Some of the light not transmitted through the material or device may be scattered, reflected, or absorbed by the materials. Visibly transparent materials are generally considered at least partially see-through (i.e., not completely opaque) when viewed by a human. A visibly transparent photovoltaic device may be simply referred to as a transparent photovoltaic (TPV) device.

As used herein, the term “transmission coefficient,” or “transmissivity” may refer to a photopically weighted transmissivity for a light wavelength or over a range or band of wavelengths, such as the visible band, or may be represented by the average or lowest transmission rate over a band or sub-band of wavelengths. For example, an average visible transmissivity (AVT) may be used to characterize the overall transmissivity of a material or device for all visible light.

As used herein, the term “color neutral” or “visibly color neutral” may refer to a color of neutral tone that is close to white or gray colors, where a gray color may be a color of neutral tone between black and white. A device or material may be color neutral if the transmissivity, absorptivity, and/or reflectivity of the device or material is substantially uniform within the visible light band, such as with a variation less than about 20%, less than about 10%, less than about 5%, or lower of an average value, such that a white light beam (including a combination of light in different colors) may remain color neutral (e.g., in white or gray color) after passing through the device or material. For example, a device or material may be color neutral if the transmissivity of the device or material at different wavelengths of the visible band (e.g., from about 400 nm to about 700 nm) are within ±10% of the AVT of the device or material. In some embodiments, a device or material may be color neutral if, when illuminated by white light, the light transmitted by the device or material has a CIELAB a* value within, for example, [−5, 5] or [−10, 10], and a CIELAB b* value within, for example, [−5, 5] or [−10, 10], or has a* and b* value in a desired quadrant, as described in detail below. In some embodiments, a device or material may be color neutral if, when illuminated by white light, the light transmitted by the device or material has substantially equal r, g, and b values in the RGB color space.

As used herein, the term “complementary” may refer to a relationship between two materials having contrasting or opposite properties, such as the transmissivity or absorptivity of the two materials, where the two materials, when combined in suitable proportions, may have a constant overall transmissivity or absorptivity in the visible band and thus may be color neutral or visibly color neutral as described above. For example, the transmissivity (or absorptivity) of two materials may be complementary to each other when the product of the transmissivity (and thus the overall transmissivity) of the two materials remain approximately constant in the visible band.

As used herein, the term “maximum absorption strength” refers to the largest absorption value in a particular spectral region, such as the ultraviolet band (200 nm to 450 nm or 280 nm to 450 nm), the visible band (450 nm to 650 nm), or the near-infrared band (650 nm to 1400 nm). In some examples, a maximum absorption strength may correspond to an absorption strength of an absorption feature that is a local or absolute maximum, such as an absorption band or peak, and may be referred to as a peak absorption. In some examples, a maximum absorption strength in a particular band may not correspond to a local or absolute maximum but may instead correspond to the largest absorption value in the particular band. Such a configuration may occur, for example, when an absorption feature spans multiple bands (e.g., visible and near-infrared), and the absorption values from the absorption feature that occur within the visible band are smaller than those occurring within the near-infrared band, such as when the peak of the absorption feature is located within the ultraviolet band but a tail of the absorption feature extends to the visible band. In some embodiments, a visibly transparent photoactive compound described herein may have an absorption peak at a wavelength greater than about 650 nanometers (i.e., in the near-infrared) or at a wavelength less than about 450 nanometers (i.e., in the ultraviolet), and the visibly transparent photoactive material's absorption peak may be greater than the visibly transparent photoactive material's absorption at any wavelength between about 450 and 650 nanometers.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

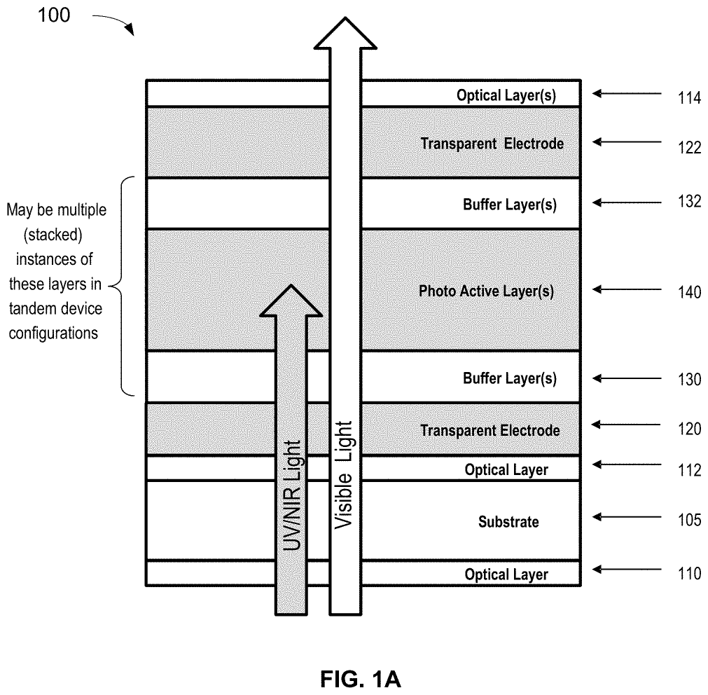

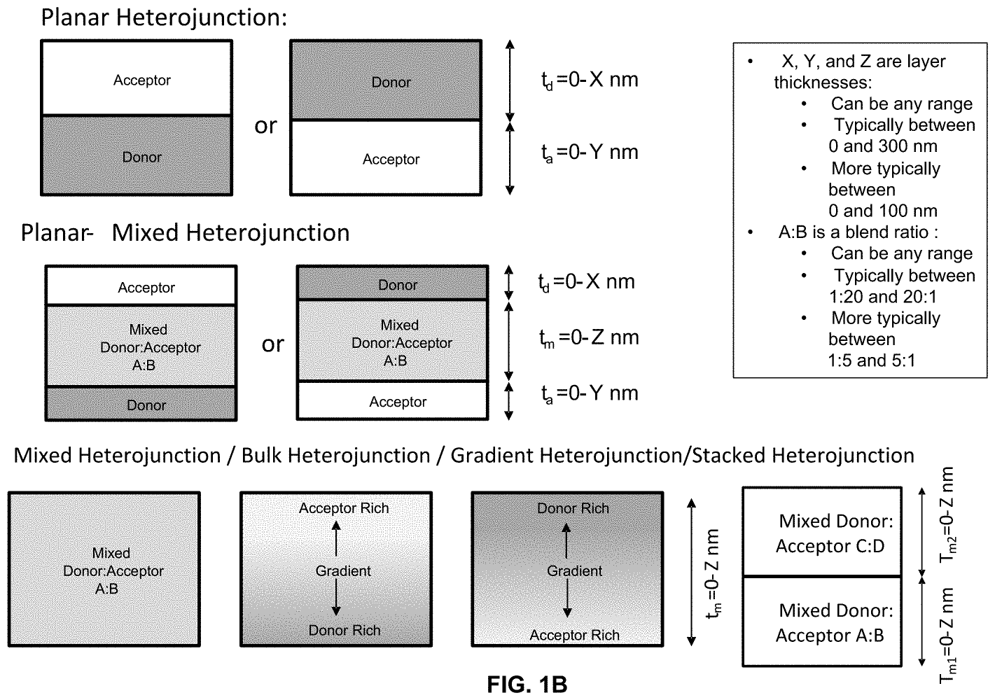

FIG. 1A is a simplified diagram illustrating an example of a visibly transparent photovoltaic (TPV) device 100 that is color neutral in the visible band according to certain embodiments. As illustrated in FIG. 1A, visibly transparent photovoltaic device 100 may include a number of layers and elements. As described above, visibly transparent indicates that the photovoltaic device absorbs optical energy at wavelengths outside the visible wavelength band of, for example, about 450 nm to about 650 nm, while substantially transmitting light inside the visible wavelength band. As illustrated in the example, UV and/or NIR light may be strongly absorbed by the layers and elements of the photovoltaic device while visible light may be substantially transmitted through the device.

Visibly transparent photovoltaic (TPV) device 100 may include a substrate 105, which can be glass or other visibly transparent materials providing sufficient mechanical support to the other layers and structures illustrated. Example substrate materials include various glasses and rigid or flexible polymers. Multilayer substrates, such as laminates, may also be utilized. Substrates may have any suitable thickness to provide the mechanical support needed for the other layers and structures, such as, for example, thicknesses from 0.5 mm to 20 mm. In some cases, the substrate may include an adhesive film to allow application of the visibly transparent photovoltaic device 100 to another structure, such as a window pane, display device, and the like. Substrate 105 may support optical layers 110 and 112. These optical layers can provide a variety of optical properties, including antireflection (AR) properties, wavelength selective reflection or distributed Bragg reflection properties, index matching properties, encapsulation, or the like. Optical layers 110 and 112 may advantageously be visibly transparent. An additional optical layer 114 can be utilized, for example, as an AR coating, an index matching later, a passive visible light, infrared light, or ultraviolet light absorption layer, and the like. Optionally, optical layers 110-114 may be transparent to visible light, ultraviolet light, and/or near-infrared light or transparent to at least a subset of wavelengths in visible, ultraviolet, and/or near-infrared bands. Depending on the configuration, additional optical layer 114 may also be a passive visible light absorption layer.

Although the devices overall may exhibit visible transparency, such as a transparency in the 450-650 nm range greater than 30%, greater than 40%, greater than 50%, greater than 60%, greater than 70%, or up to or approaching 100%, certain materials taken individually may exhibit absorption in at least some portions of the visible spectrum. Optionally, each individual material or layer in a visibly transparent photovoltaic device may have a high transparency in the visible range, such as greater than 30% (e.g., between 30% and 100%). Transmission or absorption may be expressed as a percentage and may be dependent on the material's absorbance properties, a thickness or path length through an absorbing material, and a concentration of the absorbing material, such that a material with an absorbance in the visible band may exhibit a low absorption or high transmission if the path length through the absorbing material is short and/or the absorbing material is present in low concentration.

As described herein and below, photoactive materials in various photoactive layers may advantageously exhibit minimal absorption in the visible band (e.g., less than 20%, less than 30%, less than 40%, less than 50%, less than 60%, or less than 70%), and high absorption in the near-infrared and/or ultraviolet bands (e.g., an absorption peak of greater than 50%, greater than 60%, greater than 70%, or greater than 80%). For some applications, the absorption in the visible band may be as large as 70%. Various configurations of other materials, such as the substrate, optical layers, and buffer layers, may allow these materials to provide overall visible transparency, even though the materials may exhibit some amount of visible absorption. For example, a thin film of a metal, such as Ag or Cu, may be included in a transparent electrode. The metal may absorb visible light; however, when provided in a thin film configuration, the overall transparency of the film may be high. Similarly, materials included in an optical or buffer layer may exhibit absorption in the visible range, but may be provided at a concentration or thickness such that the overall amount of visible light absorption is low, providing visible transparency.

Visibly transparent photovoltaic device 100 may include a set of transparent electrodes 120 and 122 with a photoactive layer 140 positioned between electrodes 120 and 122. Electrodes 120 and 122, which can be fabricated using ITO, thin metal films, or other suitable visibly transparent materials, provide electrical connection to one or more of the various layers illustrated. For example, thin films of copper, silver, or other metals may be suitable for use as a visibly transparent electrode, even though these metals may absorb light in the visible band. When provided as a thin film, such as a film having a thickness about 1 nm to about 200 nm (e.g., about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 105 nm, about 110 nm, about 115 nm, about 120 nm, about 125 nm, about 130 nm, about 135 nm, about 140 nm, about 145 nm, about 150 nm, about 155 nm, about 160 nm, about 165 nm, about 170 nm, about 175 nm, about 180 nm, about 185 nm, about 190 nm, or about 195 nm), an overall transmittance of the thin film in the visible band may remain high, such as greater than 30%, greater than 40%, greater than 50%, greater than 60%, greater than 70%, greater than 80%, or greater than 90%. Advantageously, thin metal films, when used as transparent electrodes, may exhibit lower absorption in the ultraviolet band than some semiconducting materials that may be useful as a transparent electrode, such as ITO, as some semiconducting transparent conducting oxides may have a band gap in the ultraviolet band and thus may be highly absorbing or opaque to ultraviolet light. In some cases, however, an ultraviolet absorbing transparent electrode may be used, such as to screen at least a portion of the ultraviolet light from underlying components, because ultraviolet light may degrade certain materials.

A variety of deposition techniques may be used to generate a transparent electrode, including vacuum deposition techniques, such as atomic layer deposition, chemical vapor deposition, physical vapor deposition, thermal evaporation, sputter deposition, epitaxy, and the like. Solution based deposition techniques, such as spin-coating, may also be used in some cases. In addition, transparent electrodes may be patterned using techniques for microfabrication, including lithography, lift off, etching, and the like.

Buffer layers 130 and 132 and photoactive layer 140 are utilized to achieve the electrical and optical properties of the photovoltaic device. These layers can be layers of a single material or can include multiple sub-layers as appropriate for the particular application. Thus, the term “layer” is not intended to denote a single layer of a single material, but can include multiple sub-layers of the same or different materials. In some embodiments, buffer layer 130, photoactive layer(s) 140, and buffer layer 132 are repeated in a stacked configuration to provide tandem device configurations, such as multi-junction cells. In some embodiments, photoactive layer(s) 140 may include electron donor materials and electron acceptor materials, also referred to as donors and acceptors. These donors and acceptors are visibly transparent, but may absorb outside the visible wavelength band to generate photocurrent.

Buffer layers 130 and 132 may function as electron transport layers, electron blocking layers, hole transport layers, hole blocking layers, exciton blocking layers, optical spacers, physical buffer layers, charge recombination layers, charge generation layers, or the like. Buffer layers 130 and 132 may have any suitable thickness to provide the buffer effect desired and may optionally be present or absent. Buffer layers 130 and 132, when present, may have thicknesses from about 1 nm to about 100 nm. Additionally, buffer layers 130 and 132 may have absorptivity complimentary to photoactive layers in some embodiments. Various materials may be used as buffer layers, including fullerene materials, carbon nanotube materials, graphene materials, metal oxides, such as molybdenum oxide, titanium oxide, zinc oxide, and the like, polymers, such as poly(3,4-ethylenedioxythiophene), polystyrene sulfonic acid, polyaniline, and the like, copolymers, polymer mixtures, and small molecules, such as bathocuproine. Buffer layers may be formed using a deposition process (e.g., thermal evaporation) or a solution processing method (e.g., spin coating), and may include one or more layers.

It is noted that, in various embodiments, visibly transparent photovoltaic device 100 may include transparent electrode 120, photoactive layer 140, and transparent electrode 122, while any one or more of substrate 105, optical layers 110, 112, and 114, and buffer layers 130 and 132 may be optionally included or excluded.

FIG. 1B illustrates various configurations of photoactive layer(s) (e.g., photoactive layer 140) in visibly transparent photovoltaic devices according to certain embodiments. Photoactive layer 140 may optionally correspond to mixed donor/acceptor (bulk heterojunction) configurations, planar donor/acceptor configurations, planar and mixed donor/acceptor configurations, gradient donor/acceptor configurations, or stacked donor/acceptor configurations. Various materials may be used as the photoactive layers 140, such as materials that absorb in the ultraviolet band or the near-infrared band but only absorb minimally, if at all, in the visible band. In this way, the photoactive material may be used to generate electron-hole pairs for powering an external circuit by way of ultraviolet and/or near-infrared absorption, while leaving the visible light relatively unaffected to provide visible transparency. In some embodiments, photoactive materials may absorb significantly in the visible spectrum to generate photocurrent. As illustrated, photoactive layer 140 may include a planar heterojunction including separate donor and acceptor layers. Photoactive layer 140 may alternatively include a planar-mixed heterojunction structure including separate acceptor and donor layers and a mixed donor-acceptor layer. Photoactive layer 140 may alternatively include a mixed heterojunction structure that includes a fully mixed acceptor-donor layer or those including a mixed donor-acceptor layer with various relative concentration gradients. Photoactive layer 140 may also include a stacked heterojunction comprising two donor/acceptor systems, such as a stacked heterojunction including two bulk heterojunctions adjacent to each other. The bulk heterojunctions may include the same donor material or the same acceptor material or different donor and acceptor materials.

In some cases, photoactive layers 140 may include individual sub-layers or mixtures of layers to provide suitable photovoltaic power generation characteristics, as illustrated in FIG. 1B. The various configurations depicted in FIG. 1B may be used based on the particular donor and acceptor materials used for photovoltaic power generation. For example, some donor and acceptor combinations may benefit from certain particular configurations, while other donor and acceptor combinations may benefit from other particular configurations. Donor materials and acceptor materials may be provided in any ratio or concentration to provide suitable photovoltaic power generation characteristics. For mixed layers, the relative concentration of donors to acceptors may be between about 20 to 1 and about 1 to 20. Optionally, the relative concentration of donors to acceptors may be between about 10 to 1 and about 1 to 10. Optionally, donors and acceptors may be in a 1:1 ratio.

Various compounds, such as tetracyano quinoidal thiophene compounds, tetracyano indacene compounds, carbazole thiaporphyrin compounds, and/or dithiophene squarine compounds, may be used as one or more of the buffer layers, optical layers, and/or the photoactive layers. These compounds can include suitably functionalized versions for modification of the electrical and/or optical properties of the core structure. As an example, the disclosed compounds can include functional groups that decrease the absorption in the visible wavelength band from about 450 nm to about 650 nm and increase the absorption in the NIR band at wavelengths greater than about 650 nm.

Examples of materials that can be utilized as active/buffer (transport layers)/optical materials in various embodiments of the present invention include near-IR absorbing materials, UV absorbing materials, and/or materials that are characterized by strong absorption peaks in the near-IR or UV regions of the electromagnetic spectrum. Examples of near-IR absorbing materials include phthalocyanines, porphyrins, naphthalocyanines, squaraines, boron-dipyrromethenes, naphthalenes, rylenes, perylenes, para-phenylenes, tetracyano quinoidal thiophene compounds, tetracyano indacene compounds, carbazole thiaporphyrin compounds, metal dithiolates, benzothiadiazole containing compounds, dicyanomethylene indanone containing compounds, combinations thereof, and the like. Examples of UV absorbing materials include fullerenes, rylenes, pervlenes, benzimidazoles, hexacarbonitriles, triarylamines, bistriarylamines, phenanthrolines, combinations thereof, and the like.

When the materials described herein are incorporated as a photoactive layer in a transparent photovoltaic device as either an electron donor or electron acceptor, the layer thicknesses can be controlled to vary power output, absorbance, or transmittance. For example, increasing the donor or acceptor layer thickness can increase the light absorption in that layer. Photoactive layers 140 may have any suitable thickness and may have any suitable concentration or composition of photoactive materials to provide a desired level of visible light transparency and ultraviolet/near-infrared absorption characteristics. Example thicknesses of a photoactive layer may range from about 1 nm to about 1 μm, about 1 nm to about 300 nm, or about 1 nm to about 100 nm. In some cases, increasing a concentration of donor/acceptor materials in a donor or acceptor layer may similarly increase the light absorption in that layer. However, in some embodiments, a concentration of donor/acceptor materials may not be adjustable, such as when active material layers comprise pure or substantially pure layers of donor/acceptor materials or pure or substantially pure mixtures of donor/acceptor materials. Optionally, donor/acceptor materials may be provided in a solvent or suspended in a carrier, such as a buffer layer material, in which case the concentration of donor/acceptor materials may be adjusted. In some embodiments, the donor layer concentration is selected such that the current produced is maximized. In some embodiments, the acceptor layer concentration is selected such that the current produced is maximized.

In some embodiments, the charge collection efficiency may decrease with increasing donor or acceptor thickness due to the increased “travel distance” for the charge carriers as well as reduced effective field across the device. Therefore, there may be a trade-off between increasing the absorption and decreasing the charge collection efficiency with increasing layer thickness. It can thus be advantageous to select materials as described herein that have a high absorption coefficient and/or concentration to allow for increased light absorption per unit thickness.

In addition to the individual photoactive layer thicknesses formed from materials described herein, the thickness and composition of other layers in the transparent photovoltaic device can also be selected to enhance absorption within the photoactive layers. The other layers (e.g., buffer layers, electrodes, etc.) may be selected based on their optical properties (index of refraction and extinction coefficient) in the context of the thin film device stack and resultant optical cavity. For example, a near-infrared absorption photoactive layer can be positioned in the peak of the optical field for the near-infrared wavelengths where it absorbs to maximize absorption and resultant photocurrent produced by the device. This can be accomplished by spacing the photoactive layer at an appropriate distance from the electrode using a second photoactive layer and/or optical layers as spacer. A similar scheme can be used for ultraviolet absorbing photoactive layers. In many cases, the peaks of the longer wavelength optical fields may be positioned further from the more reflective one of the two transparent electrodes compared to the peaks of the shorter wavelength optical fields. Thus, when using separate donor and acceptor photoactive layers, the donor and acceptor can be selected to position the more red absorbing (longer wavelength) material further from the more reflective electrode and the more blue absorbing (shorter wavelength) closer to the more reflective electrode. Alternatively, the donor and acceptor layers may be positioned in the opposite orientation to modulate their overall absorption to achieve a more neutral color at the expense of photocurrent generation.

In some embodiments, optical layers may be included to increase the intensity of the optical field at wavelengths where the donor absorbs in the donor layer to increase light absorption, and thus increase the current produced by the donor layer. In some embodiments, optical layers may be included to increase the intensity of the optical field at wavelengths where the acceptor absorbs in the acceptor layer to increase light absorption, and thus increase the current produced by the acceptor layer. In some embodiments, optical layers may be used to improve the transparency of the stack by either decreasing visible absorption or visible reflection. Further, the electrode material and thickness may be selected to enhance absorption outside the visible range within the photoactive layers, while preferentially transmitting light within the visible range. In some embodiments, the optical layers may include visibly absorbing material used to improve the uniformity of the transmissivity in the visible band as described in detail below.

Optionally, enhancing spectral coverage of a visibly transparent photovoltaic device is achieved by the use of a multi-cell serial stack of visibly transparent photovoltaic devices, referred to as tandem cells, which may be included as multiple stacked instances of buffer layer 130, photoactive layer 140, and buffer layer 132, as described with reference to FIG. 1A. This architecture includes more than one photoactive layer, which may be separated by a combination of buffer layer(s), charge recombination layers, and/or thin metal layers, for example. In this architecture, the currents generated in each subcell flow in series to the opposing electrodes, and thus the net current in the cell is limited by the smallest current generated by a particular subcell, for example. The open circuit voltage (VOC) is equal to the sum of the VOCs of the subcells. By combining subcells fabricated with different donor-acceptors pairs which absorb in different regions of the solar spectrum to generate photocurrent, a significant improvement in efficiency relative to a single junction cell can be achieved by the addition of VOC of single cells.

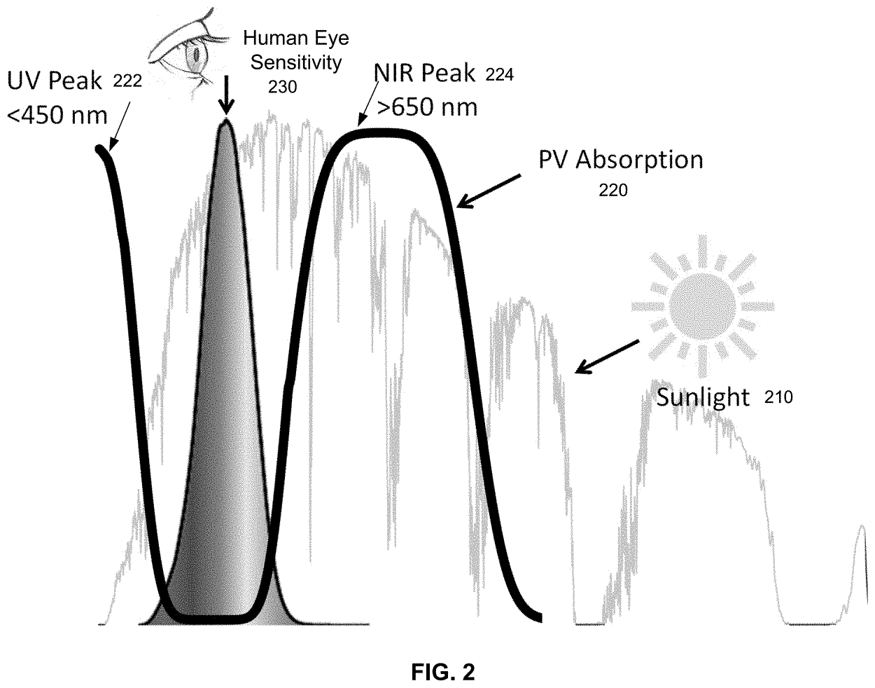

FIG. 2 is simplified plot 200 illustrating the solar spectrum 210, human eye sensitivity 230, and the absorption spectrum 220 of an example of a transparent photovoltaic device as a function of light wavelength. As illustrated in FIG. 2, embodiments of the present invention utilize photovoltaic structures that have low and uniform absorption in the visible wavelength band between about 450 nm and about 650 nm, but strongly absorb in the UV and NIR bands, i.e., outside the visible wavelength band, enabling visibly transparent photovoltaic operation. The ultraviolet band may be described, in embodiments, as wavelengths of light between about 200 nm and about 450 nm. It will be appreciated that useful solar radiation at ground level may have limited amounts of ultraviolet light with wavelengths less than about 280 nm, and thus, in some embodiments, the ultraviolet band or ultraviolet region may be described as wavelengths of light between about 280 nm and 450 nm. The near-infrared band may be described, in embodiments, as wavelengths of light of between about 650 nm and about 1400 nm. Various compositions described herein may exhibit absorption including a UV peak 222 and/or a NIR peak 224, and a maximum absorption strength in the visible band smaller than that in the NIR region or UV region.

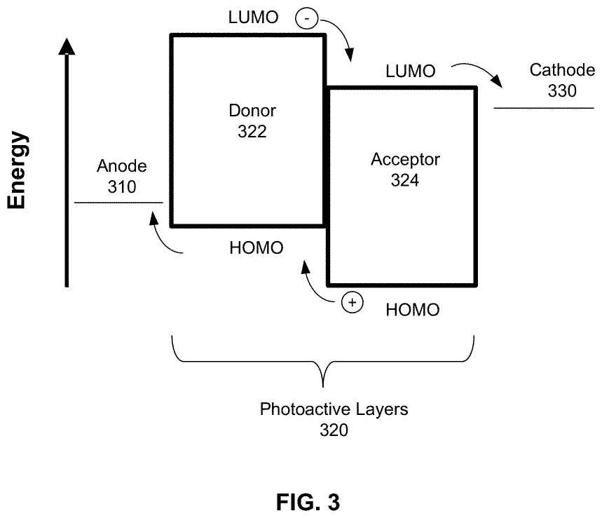

FIG. 3 is a simplified energy level diagram of an example of a visibly transparent photovoltaic device 300 according to certain embodiments, such as visibly transparent photovoltaic device 100. Visibly transparent photovoltaic device 300 may include a transparent anode 310, photoactive layers 320, and a transparent cathode 330. Photoactive layers 320 may include at least a donor material 322 and an acceptor material 324. As described above, various photoactive materials may exhibit electron donor or electron acceptor characteristics, depending on their molecular properties and the types of materials that are used for buffer layers, electrodes, and the like. As depicted in FIG. 3, each of donor material 322 and acceptor material 324 may have a highest occupied molecular orbital (HOMO) level and a lowest unoccupied molecular orbital (LUMO) level. A transition of an electron from the HOMO level to the LUMO level may occur due to absorption of photons. The energy difference between the HOMO level and the LUMO level (i.e., the HOMO-LUMO gap) of a material represents approximately the energy of the optical band gap of the material. For the electron donor and electron acceptor materials for the transparent photovoltaic devices provided herein, the HOMO-LUMO gap for the electron donor and electron acceptor materials preferably falls outside the energy band of photons in the visible range. For example, the HOMO-LUMO gap may be in the ultraviolet band or the near-infrared band, depending on the photoactive materials. It will be appreciated that the HOMO is comparable to the valence band in conventional conductors or semiconductors, while the LUMO is comparable to the conduction band in conventional conductors or semiconductors.

The narrow absorption spectrum of many organic molecules, such as organic semiconductors, can make it difficult to absorb the entire absorption spectra using a single molecular species. Therefore, electron donor and acceptor molecules are generally paired to provide complementary absorption spectra and thus increase spectral coverage of light absorption. Additionally, the donor and acceptor molecules are selected such that their energy levels (HOMO and LUMO) lie favorably with respect to one another. The difference in the LUMO level of donor and acceptor provides a driving force for dissociation of electron-hole pairs (excitons) created in the donor whereas the difference in the HOMO levels of donor and acceptors provides driving force for dissociation of electron-hole pairs (excitons) created in the acceptor. In some embodiments, it may be useful for the acceptor to have high electron mobility to efficiently transport electrons to an adjacent buffer layer or electrode. In some embodiments, it may be useful for the donor to have high hole mobility to efficiently transport holes to the adjacent buffer layer or electrode. Additionally, in some embodiments, it may be useful to increase the difference in the LUMO level of the acceptor and the HOMO level of the donor to increase the open circuit voltage (VOC), since VOC has been shown to be directly proportional to the difference between the LUMO level of the acceptor and the HOMO level of the donor. Such donor-acceptor pairings within the photoactive layer may be accomplished by appropriately pairing one of the materials described herein with a complementary material, which may be a different visibly transparent photoactive compound described herein or a completely separate material system.

The buffer layer adjacent to the donor, generally referred to as the anode buffer layer or hole transport layer or the electron blocking layer, is selected such that HOMO level or valence band (in the case of inorganic materials) of the buffer layer is aligned with the HOMO level of the donor to transport holes from the donor to anode 310 (transparent electrode). In some embodiments, it may be useful for the buffer layer to have a shallow LUMO level. In some embodiments, it may be useful for the buffer layer to have high hole mobility. The buffer layer adjacent to the acceptor, generally referred to as the cathode buffer layer or electron transport layer or hole blocking layer, is selected such that LUMO level or conduction band (in the case of inorganic materials) of the buffer layer is aligned with the LUMO level of the acceptor to transport electrons from the acceptor to cathode 330 (transparent electrode). In some embodiments, it may be useful for the buffer layer to have a deep HOMO level. In some embodiments, it may be useful for the buffer layer to have high electron mobility.

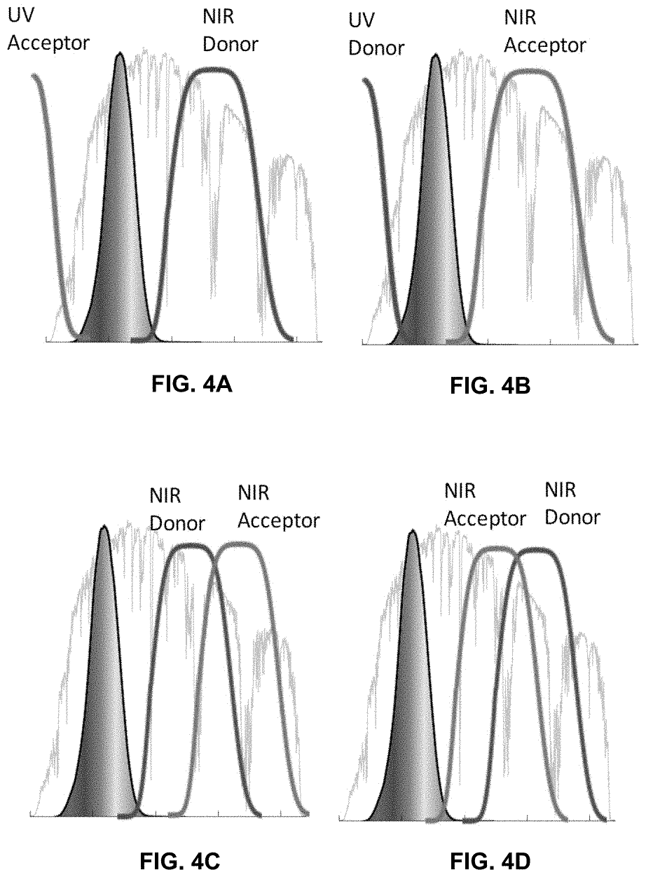

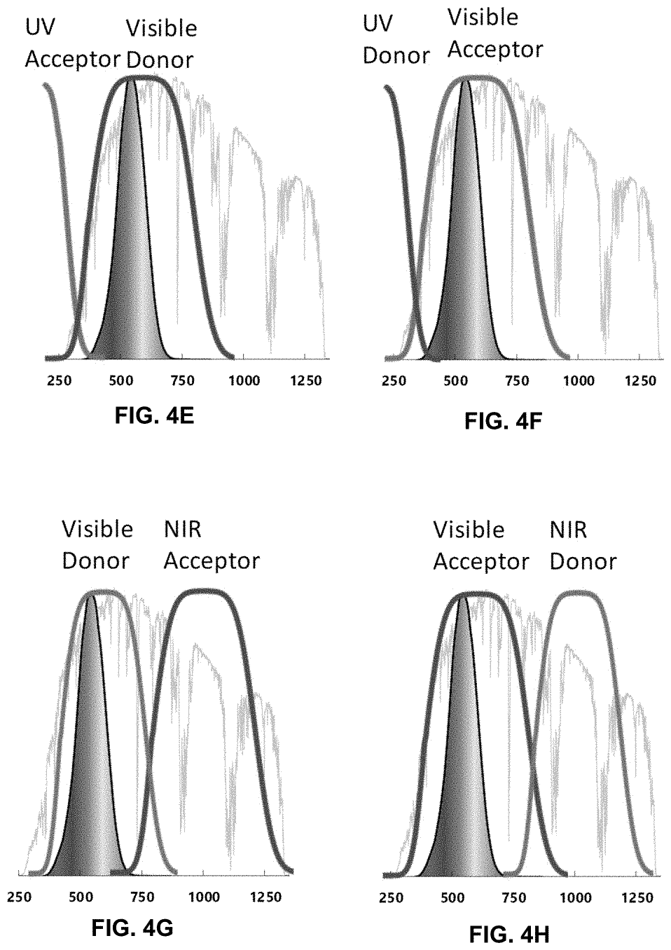

FIGS. 4A-4H illustrate absorption profiles of examples of photoactive layers with different electron acceptor and donor configurations. For example, in the example shown in FIG. 4A, the donor material exhibits absorption in the NIR band, while the acceptor material exhibits absorption in the UV band. FIG. 4B depicts a configuration opposite to the configuration shown in FIG. 4A, where the donor material exhibits absorption in the UV band, while the acceptor material exhibits absorption in the NIR band.

FIG. 4C depicts an additional configuration, where both the donor and acceptor materials exhibit absorption in the NIR band. As illustrated in the figures, the solar spectrum exhibits significant amounts of radiation in the NIR band with only relatively minor amounts in the ultraviolet band, making the configuration depicted in FIG. 4C useful for capturing a large amount of energy from the solar spectrum. It will be appreciated that other embodiments are contemplated where both the donor and acceptor materials exhibit absorption in the NIR band, such as the example depicted in FIG. 4D where the acceptor is blue shifted relative to the donor, opposite to the configuration depicted in FIG. 4C, where the donor is blue shifted relative to the acceptor.

FIG. 4E depicts a configuration where the donor material absorbs in the visible band, whereas the acceptor absorbs in the UV band. FIG. 4F represents an opposite configuration where the acceptor material absorbs in the visible band and the donor absorbs in the UV band.

FIG. 4G depicts a configuration where the donor material absorbs in the visible band, whereas the acceptor absorbs in the NIR band. FIG. 4H represents an opposite configuration where the acceptor material absorbs in the visible band and the donor absorbs in the NIR band.

A variety of compounds can be used as the photoactive compounds in the visibly transparent photovoltaic devices decribed above and below. For example, the photoactive compounds may optionally exhibit a peak absorption in the near-infrared band. Optionally, the photoactive compounds may have a peak absorption in the ultraviolet band. To achieve desired optical properties, visibly transparent photoactive compounds may have a molecular electronic structure for absorbing photons of ultraviolet or near-infrared light, which may result in the promotion of an electron from a lower molecular orbital level to a higher molecular orbital level, where an energy difference between the lower molecular orbital level to the higher molecular orbital level may match the energy of the absorbed photon. Compounds exhibiting extended aromaticity or extended conjugation are beneficial, as compounds with extended aromaticity or extended conjugation may exhibit electronic absorption with energies matching that of ultraviolet and/or near-infrared photons. In some cases, however, extended aromaticity or extended conjugation may result in absorption in the visible band (i.e., between about 450 nm and about 650 nm) as well. In addition to conjugation and aromaticity, absorption features may be modulated by inclusion of heteroatoms in the organic structure of the visibly transparent photoactive compounds, such as nitrogen or sulfur atoms. Additionally or alternatively, absorption features may be modulated by the presence and positions of metal atoms and organo metallic bonding. Additionally or alternatively, absorption features may be modulated by the presence and positions of electron donating or electron withdrawing groups, such as halogen atoms, alkyl groups, alkoxy groups, and the like, bonded to a core or sub-structure of the visibly transparent photoactive compounds. Further, absorption features may optionally be modulated by the presence of electron donor groups or electron acceptor group within a photoactive compound.

Examples of photoactive compounds that may be used for a photoactive layer in a visibly transparent photovoltaic device include those incorporating quinoidal structures, tetracyano quinoidal thiophene structures, tetracyano indacene structures, carbazole thiaporphyrin structures, and dithiophene squarine structures.

The other layers used in the visibly transparent photovoltaic devices may exhibit suitable compositions and properties for operation of the transparent photovoltaic device. For example, various visibly transparent substrates may be used, such as those including transparent glasses, transparent polymers, and the like. In some embodiments, the visibly transparent substrate may be transparent to near-infrared light (e.g., light with a wavelength greater than 650 nm) and/or ultraviolet light (e.g., light with a wavelength less than 450 nm). In this way, the visibly transparent substrate may not absorb near-infrared and/or ultraviolet light that would be suitable for photovoltaic energy generation by the visibly transparent photovoltaic devices. In some embodiments, however, the visibly transparent substrate may absorb infrared and/or ultraviolet light, which may be useful, for example, for configurations where the visibly transparent substrate serves to block excess infrared or visible radiation incident radiation after passing through the photoactive layer(s) to prevent or reduce overall ultraviolet and/or infrared transmission. Useful visibly transparent substrates include, but are not limited to, those having thicknesses of about 50 nm to about 30 mm.

Examples of visibly transparent electrodes include indium tin oxide (ITO) or thin transparent films of conductive metals, such as copper, gold, silver, aluminum, and the like, or associated metal alloys. In cases where the visibly transparent electrodes include conductive metals, the thicknesses of the visibly transparent electrodes may be such that even though the conductive metals may be opaque in the bulk, when used as a thin film, the conductive metals may still allow for the transmission of visible light. Useful visibly transparent electrodes include, but are not limited to, those having thicknesses of about 1 nm to about 500 nm.

As described above, other layers may also be present in the visibly transparent photovoltaic devices described herein. For example, a visibly transparent photovoltaic device may optionally include one or more buffer layers, such as a first buffer layer disposed between the first visibly transparent electrode and the first visibly transparent photoactive layer and/or a second buffer layer disposed between the first (or a second) visibly transparent photoactive layer and the second visibly transparent electrode. The buffer layers may serve a variety of purposes and include various compositions. For example, in some cases, a buffer layer may include a photoactive material or compound described herein. Optionally, the buffer layers may have thicknesses of about 1 nm to about 500 nm.

TPV devices fabricated using photoactive materials that absorb light in the UV and/or NIR band of solar spectrum may absorb primarily in the UV and/or NIR band, and may also have absorption that extends from the UV or NIR band into the visible band of the solar spectrum. As a result, the TPV materials or devices may show a certain color due to the non-uniform visible light absorption. As describe above, it is often desirable to achieve a neutral color for the visibly transparent photovoltaic material and device such that the visibly transparent photovoltaic material and device may have less effect on the appearance of the structure and the outside world.

There may be several ways to characterize a color-neutral visibly transparent photovoltaic material or device. A device or material may be color neutral if the transmissivity or absorptivity of the device or material is substantially uniform within the visible light band, such as with a variation less than 30%, less than 20%, less than 10%, less than 5%, or lower of the average visible transmissivity. A device or material may be color neutral if a white light beam (including a combination of light in different colors) after passing through the device or material is in a white or gray color. For example, in some embodiments, a device or material may be color neutral if, when illuminated by white light, the light transmitted by the device or material is in certain regions in a color space, such as the International Commission on Illumination (CIE) L*a*b* (CIELAB) color space or RGB color space.

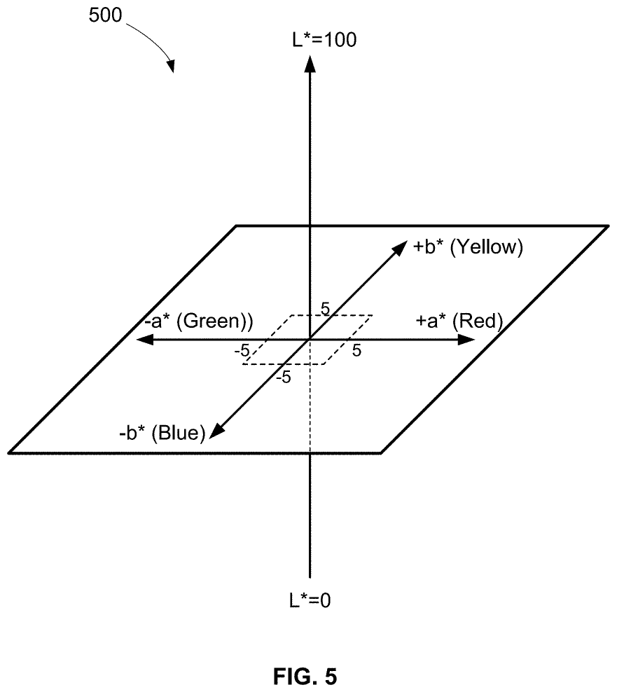

FIG. 5 illustrates the CIELAB color space for describing colors. CIE L*a*b* (CIELAB) color space describes colors visible to human eyes and is a device-independent model. The three coordinates of the CIELAB color space represent the lightness of a color, the position of the color between red/magenta and green, and the position of the color between yellow and blue. CIELAB is designed such that the same amount of numerical change in CIELAB values corresponds to approximately the same amount of visually perceived change. Unlike the RGB and CMYK color models, CIELAB color space is designed to approximate human vision.

As shown in FIG. 5, the three coordinates of the CIELAB color space are L*, a*, and b*, where the “*” is used to distinguish L*, a*, and b* from Hunter's L, a, and b. Lightness value L* represents the brightness of a color, ranging from the darkest black at L*=0 to the brightest white at L*=100. The a* axis represents the green-red component, with green in the negative direction and red in the positive direction. The b* axis represents the blue-yellow component, with blue in the negative direction and yellow in the positive direction. True neutral gray colors are represented by a*=0 and b*=0. The scaling and limits of the a* and b* axes may depend on the specific implementation. For example, in some implementations, a* and b* values may be in the range of ±100 or −128 to +127 (signed 8-bit integer). The nonlinear relations for L*, a*, and b* are intended to mimic the nonlinear response of the eye.

In some embodiments, the a* and b* values of white light after transmission through a color-neutral visibly transparent photovoltaic material or device may be within, for example, between −5 and 5, between −10 and 10, or in a particular quadrant (e.g., quadrant III, where a* and b* are both negative) in the a*-b* plane shown in FIG. 5, such that the color of the photovoltaic device or the resultant color of the white light transmitted through the photovoltaic material or device is close to a white or gray color.

In some embodiments, a transparent photovoltaic device may achieve color-neutral performance by using photoactive materials with light absorption almost only in the UV and/or NIR band and none or very little in the visible band.

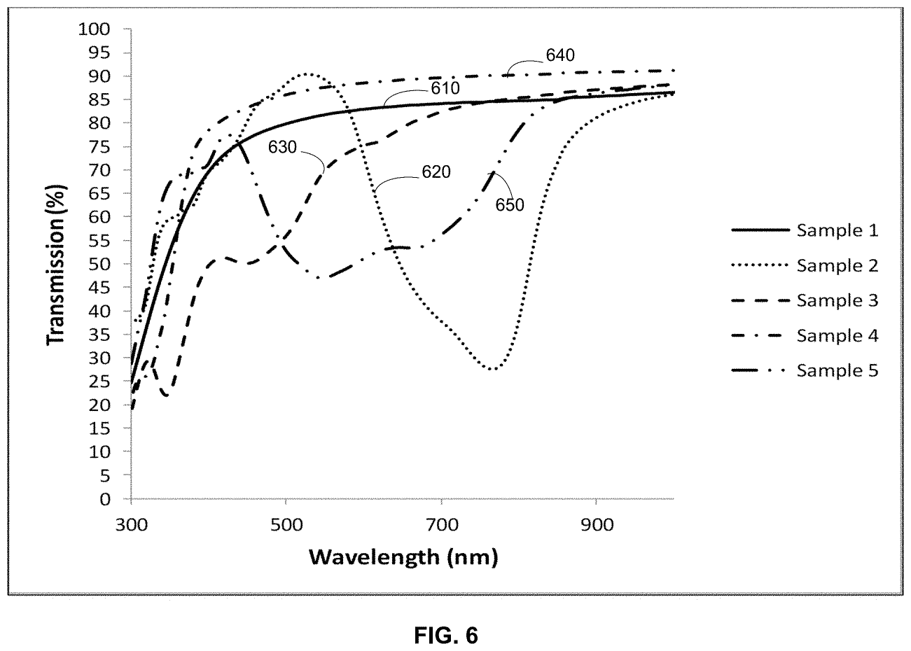

FIG. 6 illustrates transmission spectra (or curves) of samples of materials used in organic photovoltaic (OPV) devices. Spectra 610-650 in FIG. 6 show transmission coefficients of samples 1-5, respectively. As shown in FIG. 6, samples 1 and 4 may have relatively high and flat transmission coefficients in the visible band of solar spectrum, while the transmission coefficients of samples 2, 3, and 5 may have large variations in the visible band. Thus, samples 1 and 4 may absorb primarily in the UV band and may have little (and relative uniform) or no absorption in the visible band.

Table 1 shows the corresponding L*, a*, and b* values for the samples of materials used in the OPV devices shown in FIG. 6. Table 1 also shows the corresponding R, G, and B values for the samples of materials. As shown in Table 1, samples 1 and 4 have a* and b* values within [−5, 5] and close to (0,0) in the CIELAB color space, and each have substantially equal r, g, and b values in the RGB color space. Samples 2, 3, and 5 have large a* and b* values and thus are far away from the L* axis (representing neutral colors) in the CIELAB color space. Samples 2, 3, and 5 may also each have a large difference between at least two of the r, g, and b values.

TABLE 1
Color values of samples of OPV materials

| Samp. | AVT (%) | Lab L* | Lab a* | Lab b* | r | g | b |
|---|---|---|---|---|---|---|---|
| Sample 1 | 81.5 | 94.5 | −0.4 | 3.9 | 225.7 | 220.1 | 205.0 |
| Sample 2 | 82.4 | 95.0 | −16.4 | 1.5 | 158.1 | 243.9 | 216.4 |
| Sample 3 | 67.9 | 88.2 | 2.4 | 16.5 | 219.4 | 180.1 | 131.6 |
| Sample 4 | 87.4 | 97.0 | −0.3 | 3.0 | 240.5 | 236.0 | 223.4 |
| Sample 5 | 50.9 | 77.8 | 11.2 | −17.9 | 143.4 | 126.6 | 193.2 |

According to certain embodiments, a technique to achieve neutral colors for transparent PV materials or devices is to use visibly absorbing materials with transmission (absorption) spectra complementary to the transmission (absorption) spectra of materials for UV and/or NIR absorption to achieve a flat overall transmission spectrum in the visible band. In some embodiments, the neutral color may be achieved at the cost of reduced transmissivity at least at some wavelengths in the visible band and thus a decreased AVT.

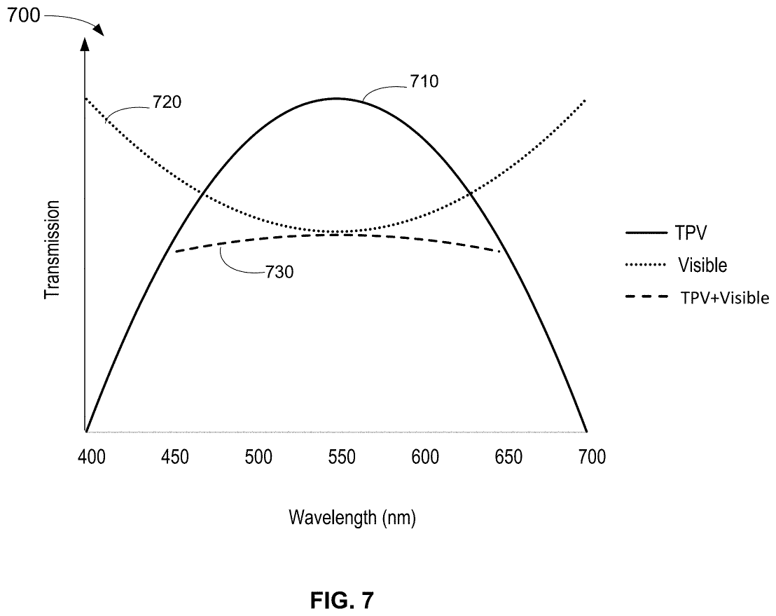

FIG. 7 is a simplified plot 700 illustrating transmission spectra (or curves) for an example of a transparent photovoltaics (TPV) material, an example of a complementary visibly absorbing material, and a combination of the TPV material with the visibly absorbing material in a device according to certain embodiments. Spectrum 710 in FIG. 7 corresponds to the transmission spectrum of the TPV material, which may have a higher transmissivity in the visible band, such as from about 450 nm to about 650 nm. However, the transmission spectrum of the TPV material shown by spectrum 710 is not flat in the visible band, and thus the TPV material may exhibit a color other than a neutral color.

Spectrum 720 corresponds to a desired transmission spectrum of the complementary visibly absorbing material. Spectrum 720 may be complementary to spectrum 710 in the visible band. For example, the TPV material may have a lower transmissivity (or higher absorptivity) at 450 nm, while the complementary visibly absorbing material may have a higher transmissivity (or lower absorptivity) at 450 nm. Thus, at 450 nm, the overall transmission of the combination of the TPV material and the complementary visibly absorbing material may be slightly lower than the transmissivity of the TPV material. At 550 nm, the TPV material may have a higher transmissivity (or lower absorptivity), while the complementary visibly absorbing material may have a lower transmissivity (or higher absorptivity). Thus, at 550 nm, the overall transmissivity of the combination of the TPV material and the complementary visibly absorbing material may be slightly lower than the transmissivity of the complementary visibly absorbing material. As such, a transmission spectrum 730 of the combination of the TPV material and the complementary visibly absorbing material may be the product of spectrum 710 and spectrum 720 at each individual wavelength and may be substantially flat in the visible band.

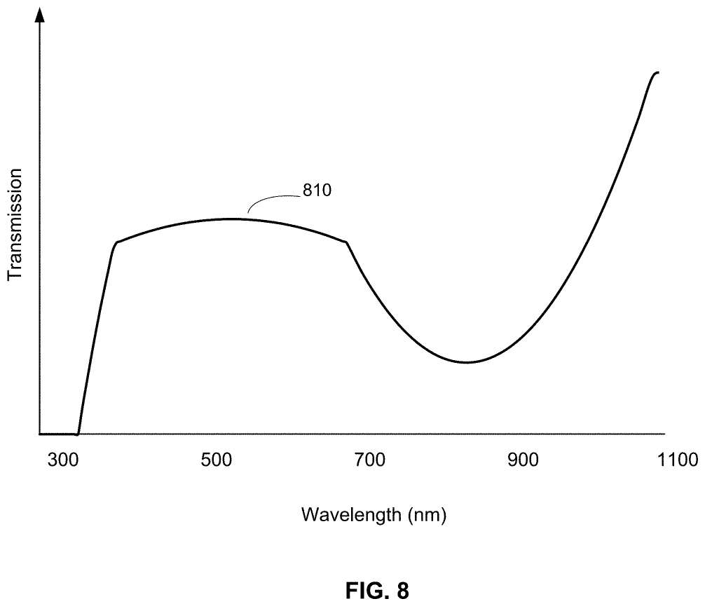

FIG. 8 illustrates an example of a transmission spectrum 810 for a color-neutral visibly transparent photovoltaic (TPV) device according to certain embodiments. The color-neutral TPV device may include a first photoactive material that is absorptive in the UV band, a second photoactive material that is absorptive in the NIR band. The color-neutral TPV device may also include a third material that is absorptive in the visible band. The third material may be passive or photoactive. In some embodiments, the third material may also be absorptive in the NIR or UV band. The third material may be added to the color-neutral TPV device to decrease the distance of a* and b* values for the TPV device from origin (0,0), to change the a* and b* values for the TPV device to a more desirable quadrant (e.g., a* and b* with negative values) in the a*-b* plane, or to reduce the variation of the transmission spectrum in the visible band to, for example, within ±10% of the AVT value from about 450 nm to about 650 nm as shown in FIG. 8. As also shown in FIG. 8, the AVT of the combination of the materials may be lower than that without the third material due to the absorption of the visible light by the third material. In some embodiments, the first or second material may include a combination of two or more materials. In some embodiments, the third material may include a combination of two or more materials.

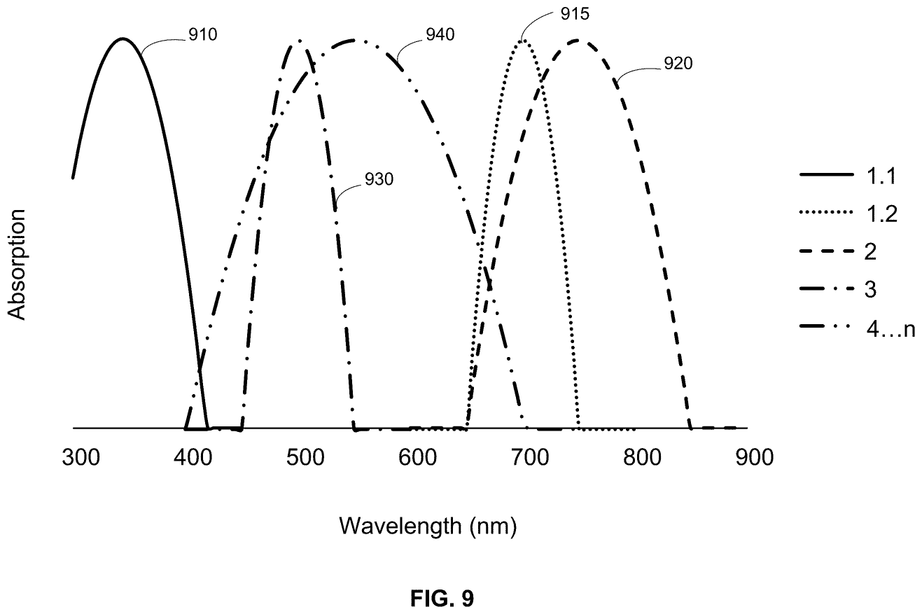

FIG. 9 illustrates examples of absorption spectra (or curves) of materials in an example of a color-neutral visibly transparent photovoltaic (TPV) device according to certain embodiments. The illustrated absorption spectra may also be referred to as the wavelength-dependent absorption coefficients of the materials. The color-neutral TPV device may include, for example, materials 1 to n, the absorption spectra of which are shown in FIG. 9. In some embodiments, materials 1 and 2 may be active materials (e.g., donor and acceptor materials) in the TPV device. For example, material 1 may be an electron acceptor material and may absorb in the UV band as shown by a spectrum 910 and/or in the NIR band as shown by a spectrum 915. In some embodiments, the electron acceptor material may include a combination of two or more materials, such as a material 1.1 (e.g., photoactive in the UV band) and a material 1.2 (e.g., photoactive in the NIR band). Material 2 may be an electron donor material and may absorb in the NIR band of the solar spectrum as shown by a spectrum 920. Materials 3, 4, . . . , and n may be visibly absorbing materials, where a material or a combination of two or more materials in materials 3-n may have an absorption spectrum complementary to the combined absorption spectra of materials 1 and 2 in the visible band. The combination of materials 1 and 2 and at least one of materials 3-n may result in a substantially flat transmission spectrum in the visible band of the solar spectrum. In some embodiments, materials 3-n may also be absorptive in the NIR or UV band.

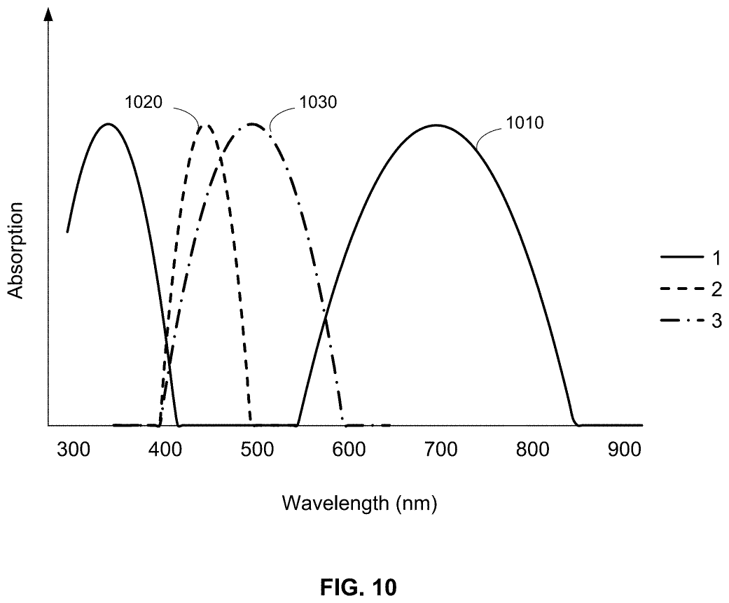

FIG. 10 illustrates absorption spectra (or curves) of examples of TPV materials and examples of visibly absorbing materials in a color-neutral TPV device according to certain embodiments. The illustrated absorption spectra may also be referred to as the wavelength-dependent absorption coefficients of the materials. Spectrum 1010 illustrates the absorption spectrum for TPV materials 1. Spectra 1020 and 1030 show absorption spectra of visibly absorbing materials 2 and 3, respectively.

In the example shown in FIG. 10, TPV materials 1 are transparent active materials in which one of the active materials (e.g., donor or acceptor material) may absorb in the NIR band and the other active material (e.g., donor or acceptor material) may absorb in the UV band. At least one of the active materials may at least partly absorb light in the visible band of the solar spectrum. Examples of TPV materials 1 include active materials, such as UE-D-100 and buckminsterfullerene (Co). Although D-100 is illustrated as an exemplary donor in the embodiment illustrated in FIG. 10, as well as in other figures included in the present specification, embodiments of the present invention are not limited to a particular example and other donors and/or combinations of donors can be utilized according to various embodiments of the present invention and are included within the scope of the present invention. Similarly, the present invention is not limited to the exemplary acceptors illustrated in the present figures and other acceptors and combinations of acceptors are included within the scope of the present invention. One of ordinary skill in the art would recognize many variations, modifications, and alternatives. TPV materials 1 may be paired with one or more materials (e.g., C₇₀ or 3,4,9,10-perylenetetracarboxylic bisbenzimidazole (PTCBI)) with a combined absorption spectrum complementary to the absorption spectrum of TPV materials in the visible band. For example, C₇₀ may absorb in the UV band and visible band, and PTCBI may absorb in the visible band and NIR band.

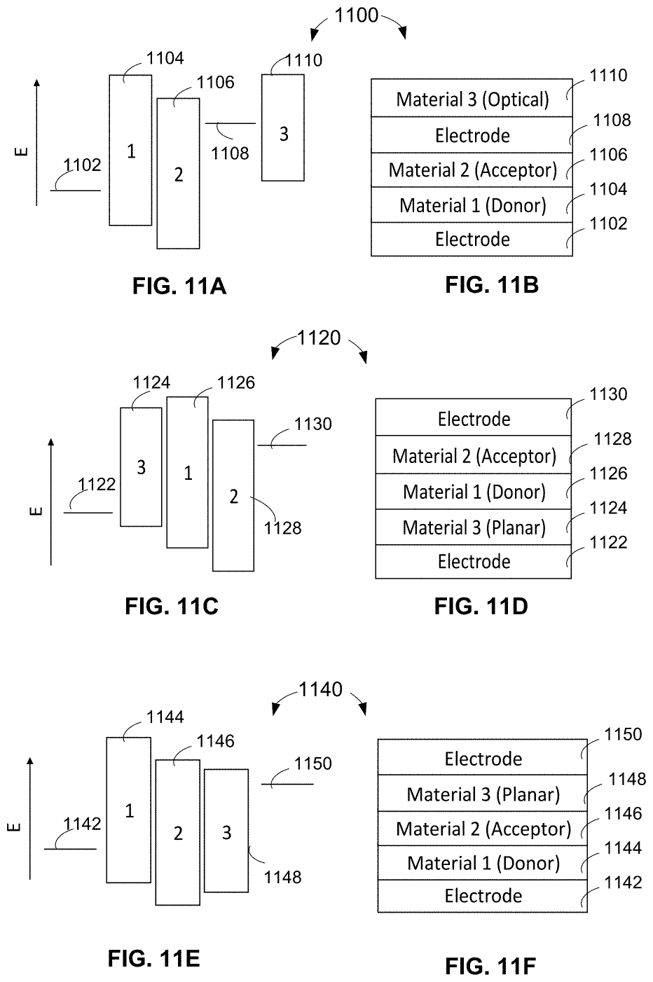

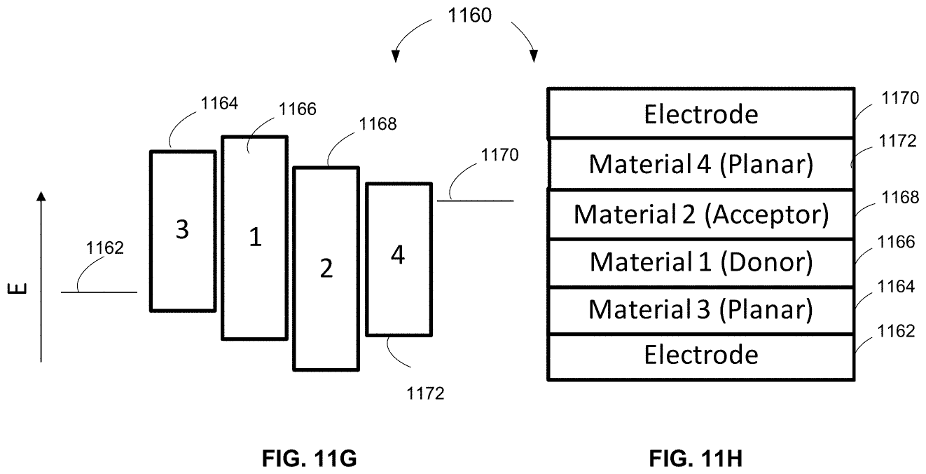

FIGS. 11A-11H illustrate device configurations and energy level alignments of examples of color-neutral TPV devices according to certain embodiments. In the examples shown in FIGS. 11A-11H, the color-neutral TPV devices each include three or more materials, which may include at least a donor material, an acceptor material, and a visible light absorption color neutralizing material. In different devices, the compositions and the energy levels of the three or more materials, and the configurations or stack-ups of the layers of the three or more materials in the devices may be different. In the examples shown in FIGS. 11A-11H, the first and second materials may be donor and acceptor materials that may absorb light in the UV band and NIR band, and material 3 may be absorptive in the visible band. In some embodiments, materials 3 and 4 may also act as electron donor or acceptor. Although not shown in FIGS. 11A-11H, the color-neutral TPV devices shown in FIGS. 11A-11H may include some other layers of materials, such as one or more buffer layers as shown and discussed with respect to FIG. 1A and FIG. 3.

FIG. 11A and FIG. 11B illustrate the energy level alignment and the structure of an example of a color-neutral TPV device 1100. Color-neutral TPV device 1100 may include a first electrode 1102 (e.g., an anode), a first material 1104 (e.g., a donor material), a second material 1106 (e.g., an acceptor material), a second electrode 1108 (e.g., a cathode), and a third material 1110. Second material 1106 may have a HOMO level deeper (i.e., lower) than the HOMO level of first material 1104 and a LUMO level deeper than the LUMO level of first material (1104) to facilitate the dissociation of excitons generated in materials 1 and 2.

In color-neutral TPV device 1100, third material 1110 is not between first electrode 1102 and second electrode 1108. Third material 1110 may be used as an optical layer to neutralize color of color-neutral TPV device 1100 but may not contribute to photocurrent. Since third material 1110 does not contribute to photocurrent, its energy levels can be positioned irrespective of the energy levels of first material 1104 and second material 1106. In some embodiments, third material 1110 may be a passive material that may absorb visible light but may not generate photocurrent (e.g., may generate heat instead).

FIG. 11C and FIG. 11D illustrate the energy level alignment and the structure of an example of a color-neutral TPV device 1120. Color-neutral TPV device 1120 may also include a first electrode 1122 (e.g., an anode), a first material 1126 (e.g., a donor material), a second material 1128 (e.g., an acceptor material), a second electrode 1130 (e.g., a cathode), and a third material 1124 between first electrode 1122 and first material 1126. Second material 1128 may have a HOMO level deeper (i.e., lower) than the HOMO level of first material 1126 and a LUMO level deeper (i.e., lower) than the LUMO level of first material 1126 to facilitate the dissociation of excitons generated in materials 1 and 2.

In color-neutral TPV device 1120, third material 1124 may forma planar layer between first electrode 1122 (e.g., anode) and first material 1126 (e.g., a donor material). Third material 1124 may be a good hole transportation material, and the HOMO level of third material 1124 may be shallower (i.e., higher) than or equal to the HOMO level of first material 1126 so that there is no energy barrier for hole transportation from first material 1126 to third material 1124 and first electrode 1122. In some embodiments, third material 1124 may be thin enough to allow for hole tunneling. Therefore, when placed next to first material 1126, third material 1124 may transport photo-generated holes to the anode (e.g., first electrode 1122). In some embodiments, the color neutralizing layer may be doped.

In some embodiments, the LUMO level of third material 1124 may be deeper (i.e., lower) than the LUMO level of first material 1126 as shown in FIG. 11C. In some embodiments, the emission spectrum of third material 1124 may overlap with the absorption spectra of first material 1126 or second material 1128, and thus third material 1124 may contribute to photocurrent.

FIG. 11E and FIG. 11F illustrate the energy level alignment and the structure of an example of a color-neutral TPV device 1140. Color-neutral TPV device 1140 may also include a first electrode 1142 (e.g., an anode), a first material 1144 (e.g., a donor material), a second material 1146 (e.g., an acceptor material), a second electrode 1150 (e.g., a cathode), and a third material 1148 between second electrode 1150 and second material 1146. Second material 1146 may have a HOMO level deeper than the HOMO level of first material 1144 and a LUMO level deeper than the LUMO level of first material 1144 to facilitate the dissociation of excitons generated in materials 1 and 2.

In color-neutral TPV device 1140, third material (1148) may be a good electron transportation material, and may have a LUMO level deeper than or equal to the LUMO level of second material so that there is no energy barrier for electron transportation from second material 1146 to third material 1148 and second electrode 1150. In some embodiments, third material 1148 may be thin enough to allow for hole tunneling. Therefore, when third material 1148 is placed next to second material 1146 (e.g., an acceptor material), third material 1148 can transport photo-generated electrons to the cathode (e.g., second electrode 1150) with no energy barrier. In some embodiments, the color neutralizing layer may be doped. In some embodiments, the emission spectrum of third material 1148 may overlap with the absorption spectra of first material 1144 or second material 1146, and thus third material 1148 may contribute to photocurrent.

FIG. 11G and FIG. 11H illustrate the energy level alignment and the structure of an example of a color-neutral TPV device 1160. Color-neutral TPV device 1160 may also include a first electrode 1162 (e.g., an anode), a first material 1166 (e.g., a donor material), a second material 1168 (e.g., an acceptor material), a second electrode 1170 (e.g., a cathode), a third material 1164 between first electrode 1162 and first material 1164, and a fourth material 1172 between second electrode 1170 and second material 1168. Third material 1164 and fourth material 1172 may be used as planar layers on either side of the donor and acceptor to achieve an overall neutral color TPV. Third material 1164 may have a similar or shallower HOMO level than first material 1166 to transport holes to the anode without any energy barrier. Fourth material 1172 may have a similar or deeper LUMO level compared to second material 1168 to efficiently transport electrons to the cathode without any energy barrier.

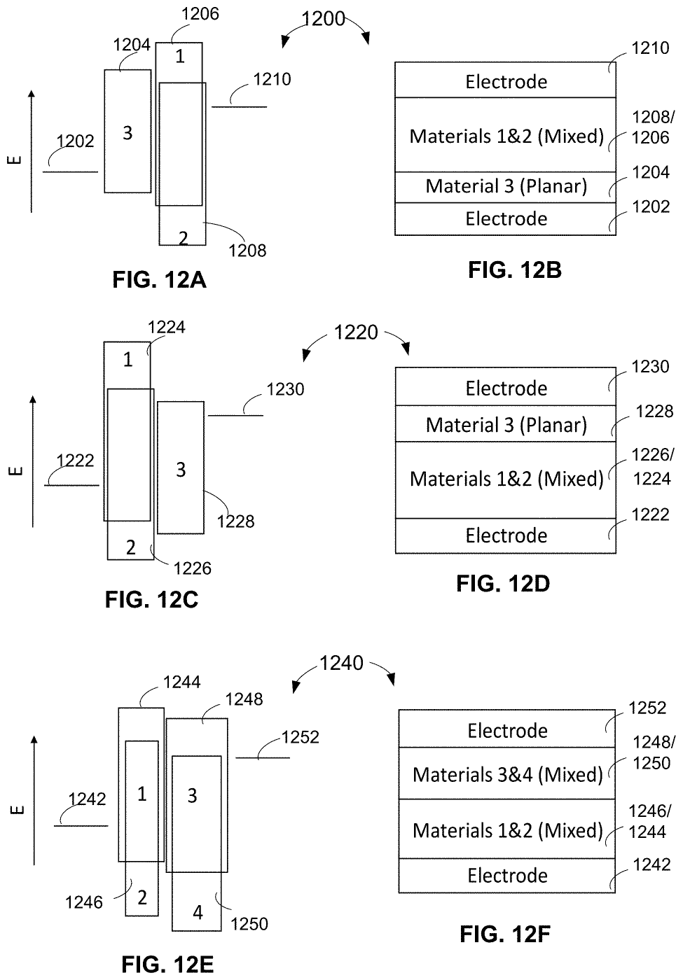

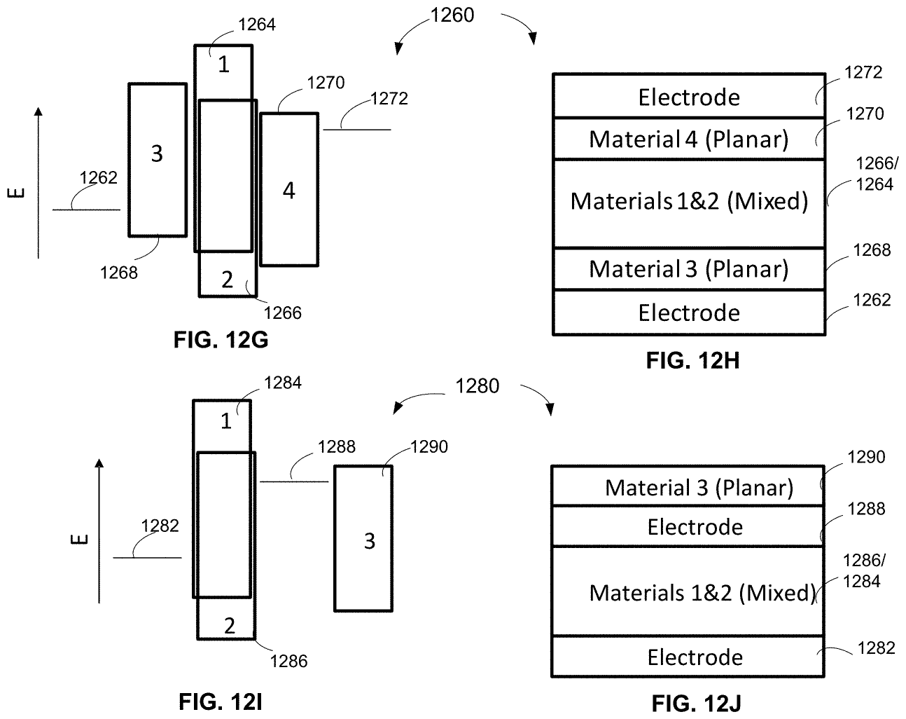

FIGS. 12A-12J illustrate device structures and energy level alignments of examples of color-neutral TPV devices according to certain embodiments. In the examples shown in FIGS. 12A-12J, the color-neutral TPV devices each include three or more materials, which may include at least a donor material, an acceptor material, and a visible light absorption color neutralizing material. In different devices, the compositions and the energy levels of the three or more materials, and the configurations or stack-ups of the layers of the three or more materials in the devices may be different. In the examples shown in FIGS. 12A-12J, the first and second materials may be donor and acceptor materials that may absorb light in the UV band and NIR band, and may be mixed to form mixed heterojunction, bulk heterojunction, or gradient heterojunction as described above with respect to FIG. 1B. The third material may be absorptive in the visible band, and may, in some embodiments, absorptive in NIR or UV band as well. Although not shown in FIGS. 12A-12J, the color-neutral TPV devices shown in FIGS. 12A-12J may include some other layers of materials, such as one or more buffer layers as shown and discussed with respect to FIG. 1A and FIG. 3.

FIG. 12A and FIG. 12B illustrate the energy level alignment and the structure of an example of a color-neutral TPV device 1200. Color-neutral TPV device 1200 may include a first electrode 1202 (e.g., an anode), a first material 1206 mixed with a second material 1208, a second electrode 1210 (e.g., a cathode), and a third material 1204 between first electrode 1202 and the mixed heterojunction formed by first material 1206 and second material 1208. Second material 1208 may have a HOMO level deeper than the HOMO level of first material 1206 and may have a LUMO level deeper than the LUMO level of first material 1206.

In color-neutral TPV device 1200, third material 1204 may form a planar layer and may be a good hole transportation material. The HOMO level of third material 1204 may be shallower than or equal to the HOMO level of first material 1206 so that there is no energy barrier for hole transportation from the HOMO level of first material 1206 to the HOMO level of third material 1204 and the anode (e.g., first electrode 1202). Therefore, when placed next to first material 1206 (e.g., a donor material), third material 1204 may transport photo-generated holes to the anode (e.g., first electrode 1202). In embodiments where the LUMO level of third material 1204 is shallower than the LUMO level of second material 1208 (e.g., an acceptor material) as shown in FIG. 12A, excitons generated in third material 1204 may be dissociated at the interface between second material 1208 and third material 1204, and thus third material 1204 may contribute to the photocurrent. If the LUMO level of third material 1204 is deeper than or equal to the LUMO level of second material 1208, third material 1204 may not contribute to the photocurrent.

FIG. 12C and FIG. 12D illustrate the energy level alignment and the structure of an example of a color-neutral TPV device 1220. Color-neutral TPV device 1220 may also include a first electrode 1222 (e.g., an anode), a first material 1224 mixed with a second material 1226, a second electrode 1230 (e.g., a cathode), and a third material 1228 between second electrode 1230 and the mixed heterojunction formed by first material 1224 and second material 1226. Second material 1226 may have a HOMO level deeper than the HOMO level of first material 1224 and may have a LUMO level deeper than the LUMO level of first material 1224.

In color-neutral TPV device 1220, third material 1228 may form a planar layer and may be a good electron transportation material. The LUMO level of third material 1228 may be deeper than or equal to the LUMO level of second material 1226 such that there is no energy barrier for electron transportation from the LUMO level of second material 1226 to the LUMO level of third material 1228 and the cathode (e.g., second electrode 1230). Therefore, when placed next to second material 1226 (e.g., an acceptor material), third material 1228 may transport photo-generated electrons to the cathode (e.g., second electrode 1230). In embodiments where the HOMO level of third material 1228 is deeper than the HOMO level of first material 1224 (e.g., a donor material), excitons generated in third material 1228 may be dissociated at the interface between first material 1224 and third material 1228, and thus third material 1228 may contribute to the photocurrent. If the HOMO level of third material 1228 is shallower than or equal to the HOMO level of first material 1224, third material 1228 may not contribute to the photocurrent.

FIG. 12E and FIG. 12F illustrate the energy level alignment and the structure of an example of a color-neutral TPV device 1240. Color-neutral TPV device 1240 may include a first electrode 1242 (e.g., an anode), a first material 1244 mixed with a second material 1246, a third material 1248 mixed with a fourth material 1250, and a second electrode 1252 (e.g., a cathode). Second material 1246 may have a HOMO level deeper than the HOMO level of first material 1244 and a LUMO level deeper than the LUMO level of first material 1244.

In color-neutral TPV device 1240, the HOMO level of first material 1244 may be shallower than or equal to the HOMO level of third material 1248 such that there is no barrier to hole transportation from third material 1248 to the anode (e.g., first electrode 1242). Similarly, the LUMO level of the fourth material 1250 may be deeper than or equal to the LUMO level of second material 1246 such that there is no barrier to electron transportation from second material 1246 to the cathode (e.g., second electrode 1252). Thus, all four materials may contribute to the photocurrent in color-neutral TPV device 1240. In some embodiments, first material 1244 and third material 1248 may be the same donor material. In some embodiments, second material 1246 and fourth material 1250 may be the same acceptor material. The four materials may be selected such that they may have complementary absorption spectra in the visible band to achieve an overall neutral color for color-neutral TPV device 1240.

FIG. 12G and FIG. 12H illustrate the energy level alignment and the structure of an example of a color-neutral TPV device 1260. Color-neutral TPV device 1260 may include a first electrode 1262 (e.g., an anode), a first material 1264 mixed with a second material 1266, a third material 1268, a fourth material 1270, and a second electrode 1272 (e.g., a cathode). Third material 1268 and fourth material 1270 may be used as planar layers on either side of the donor and acceptor to achieve an overall neutral color TPV. Third material 1168 may have a similar or shallower HOMO level than first material 1164 to transport holes to the anode without any energy barrier. Fourth material 1270 may have a similar or deeper LUMO level compared to second material 1266 to efficiently transport electrons to the cathode without any energy barrier.

FIG. 12I and FIG. 12J illustrate the energy level alignment and the structure of an example of a color-neutral TPV device 1280. Color-neutral TPV device 1280 may include a first electrode 1282 (e.g., an anode), a first material 1284 mixed with a second material 1286, a third material 1290, and a second electrode 1290 (e.g., a cathode). In color-neutral TPV device 1280, third material 1290 is not between first electrode 1282 and second electrode 1288. Third material 1290 may be used as an optical layer to neutralize color of color-neutral TPV device, but may not contribute to photocurrent. Since third material 1290 does not contribute to photocurrent, its energy levels can be positioned irrespective of the energy levels of first material 1284 and second material 1286. In some embodiments, third material 1290 may be a passive material that may absorb visible light but may not generate photocurrent (e.g., may generate heat instead).

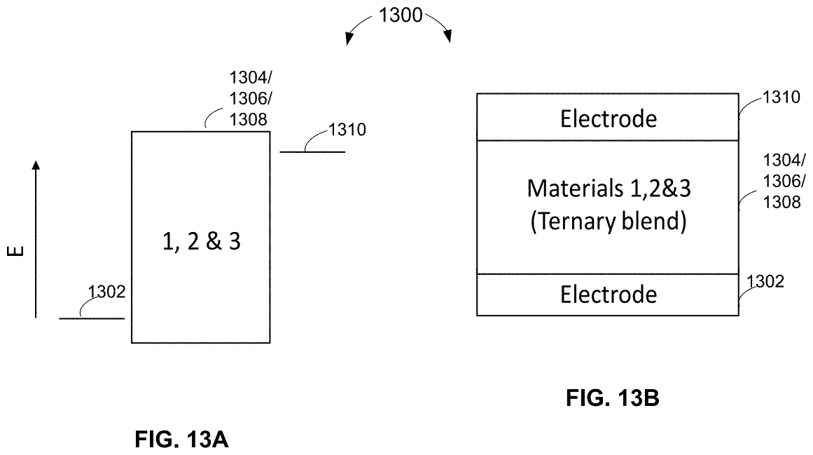

FIGS. 13A-13B illustrate the device configuration and energy level alignment of an example of a color-neutral TPV device 1300 according to certain embodiments. Color-neutral TPV device 1300 may include three or more materials, which may include at least a donor material, an acceptor material, and a visible light absorption color neutralizing material. The first and second materials may include a donor material and an acceptor material that may absorb light in the UV band and NIR band. The third material may be absorptive in the visible band, and may, in some embodiments, absorptive in NIR and/or UV band as well. The first, second, and third materials may be mixed to form a ternary blend as described above with respect to FIG. 1B.

Color-neutral TPV device 1300 may include a first electrode 1302 (e.g., an anode), a second electrode 1310, and a ternary blend of a first material 1304, a second material 1306, and a third material 1308. In the ternary blend, all three (or more) materials are mixed together. First material 1304 and second material 1306 are active materials of the transparent PVs and may contribute to the photocurrent. Third material 1308 may or may not contribute to photocurrent depending on its energy level alignment with first material 1304 and second material 1306, as described above. Although not shown in FIGS. 13A-13B, color-neutral TPV device 1300 may include some other layers of materials, such as one or more buffer layers as shown and discussed with respect to FIG. 1A and FIG. 3.

The various combinations of materials described above in relation to the color-neutral TPV devices of FIGS. 11A-13 may also be used in electrically inverted devices and tandem devices. Some examples of devices according to the structures described above are made and measured.

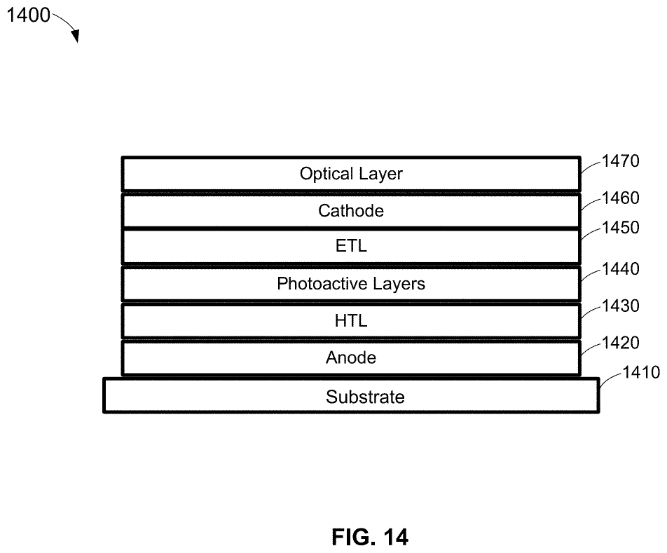

FIG. 14 illustrates an example of a color-neutral TPV device 1400 including a visible light absorption optical layer 1470 according to certain embodiments. Color-neutral TPV device 1400 may be a specific example of color-neutral TPV device 1100 described above with respect to FIGS. 11A and 11B. As illustrated, color-neutral TPV device 1400 may also include a transparent substrate 1410 (e.g., a glass substrate), a first electrode 1420, a hole transport layer 1430, photovoltaic material layers 1440 including a mixed electron donor and acceptor layer (e.g., Donor:C60), an electron transport (or buffer) layer 1450, and a second electrode 1460 (e.g., cathode) that may include, for example, a thin ITO layer and/or an Ag layer. The photovoltaic material layers may absorb light in the UV and NIR bands to generate photocurrent.

Visible light absorption optical layer 1470 may include, for example, perylenetetracarboxylic bisbenzimidazole (PTCBI):

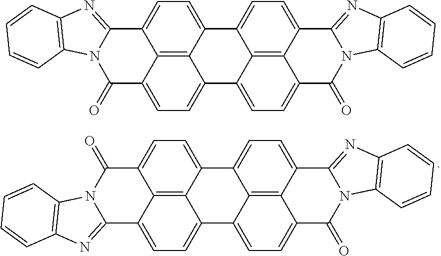

PTCBI may absorb visible and NIR light. Visible light absorption optical layer 1470 may be used as an optical layer to neutralize color of color-neutral TPV device 1400, but may not contribute to photocurrent. Since visible light absorption optical layer 1470 does not contribute to photocurrent, its energy levels can be anywhere. The thickness of visible light absorption optical layer 1470 may be tuned to tune the overall light absorption spectrum of color-neutral TPV device 1400.

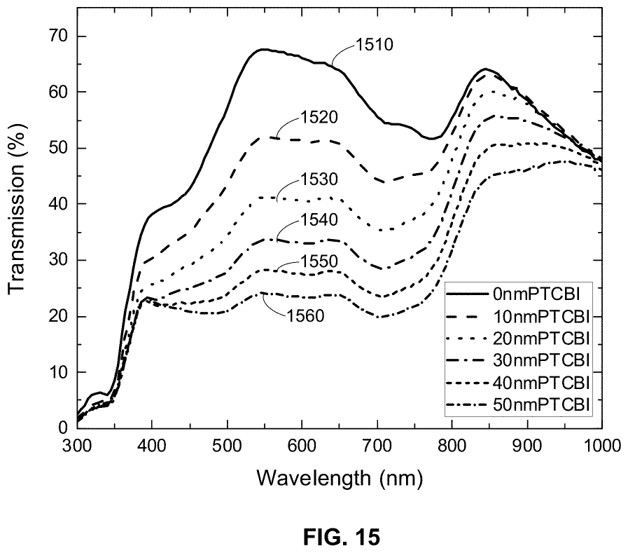

FIG. 15 illustrates simulated transmission spectra of examples of color-neutral TPV devices (e.g., color-neutral TPV device 1400) including a visible light absorption optical layer having different thicknesses according to certain embodiments. For example, spectrum 1510 shows the transmission spectrum of color-neutral TPV device 1400 when there is no PTCBI layer (e.g., visible light absorption optical layer 1490) in color-neutral TPV device 1400. Spectra 1520-1560 show the transmission spectra of color-neutral TPV device 1400 when the PTCBI layer (e.g., visible light absorption optical layer 1490) has a thickness of 10 nm, 20 nm, 30 nm, 40, nm, and 50 nm, respectively. As shown, increasing the thickness of the PTCBI layer may increase the absorption of the color-neutral TPV device in the visible and NIR bands. In the example shown in FIG. 15, when the PTCBI layer is about 50 nm, color-neutral TPV device 1400 may have a substantially flat transmission spectrum in the visible band.

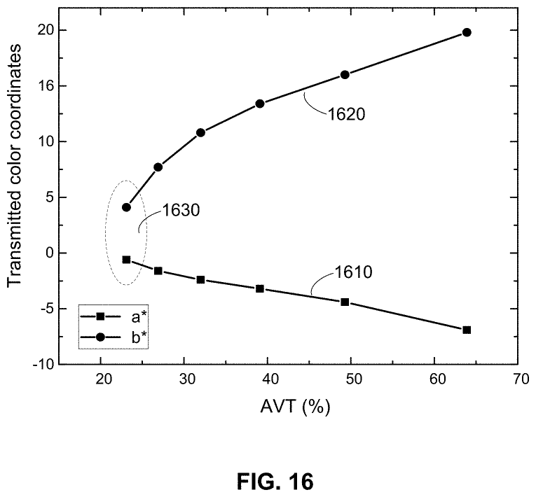

FIG. 16 illustrates examples of color coordinates of visible light transmitted through examples of color-neutral TPV devices (e.g., color-neutral TPV device 1400) including a visible light absorption optical layer having different thicknesses according to certain embodiments. For example, spectrum 1610 shows the simulated a* value of white light after transmitting through color-neutral TPV devices having PTCBI layers of different thicknesses (e.g., 0 nm, 10 nm, 20 nm, 30 nm, 40 nm, and 50 nm) and thus different AVT values as shown in FIG. 15. Spectrum 1620 shows the simulated b* value of white light after transmitting through color-neutral TPV devices having PTCBI layers of different thicknesses (e.g., 0 nm, 10 nm, 20 nm, 30 nm, 40 nm, and 50 nm) and thus different AVT values as shown in FIG. 15. As shown, when the PTCBI layer is about 50 nm, the a* and b* values of white light transmitted through the color-neutral TPV device may be close to (0, 0), such as within [−5, 5], which also indicates that the device is color neutral.

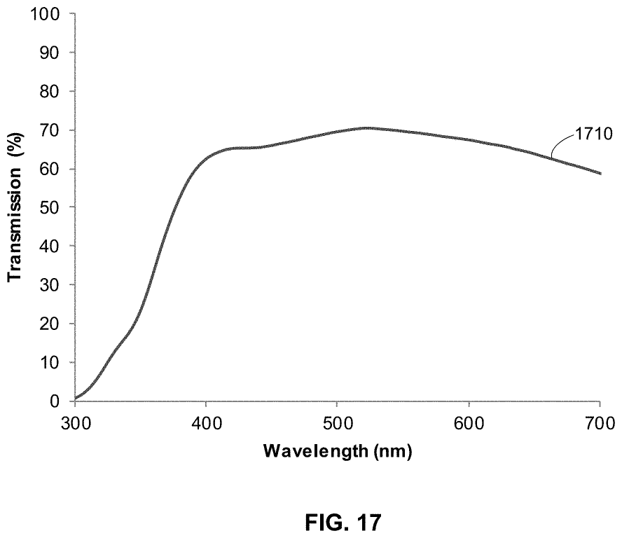

FIG. 17 illustrates an experimentally measured transmission spectrum 1710 of an example of a color-neutral TPV device according to certain embodiments. As described above, the color-neutral TPV device may include visibly absorbing materials with absorption spectrum complementary to the UV/NIR absorption materials in the stack of layers of the color-neutral TPV device. The visibly absorbing materials and the UV/NIR absorption materials may result in a flat transmission spectrum and achieve a neutral transmitted color. For example, as shown in FIG. 17, due to the complementary absorption characteristics of PTCBI to UE-D-100:C₆₀ in the visible band, a flat transmission spectrum 1710 may be achieved across the visible spectrum, which may result in a neutral transmitted color.

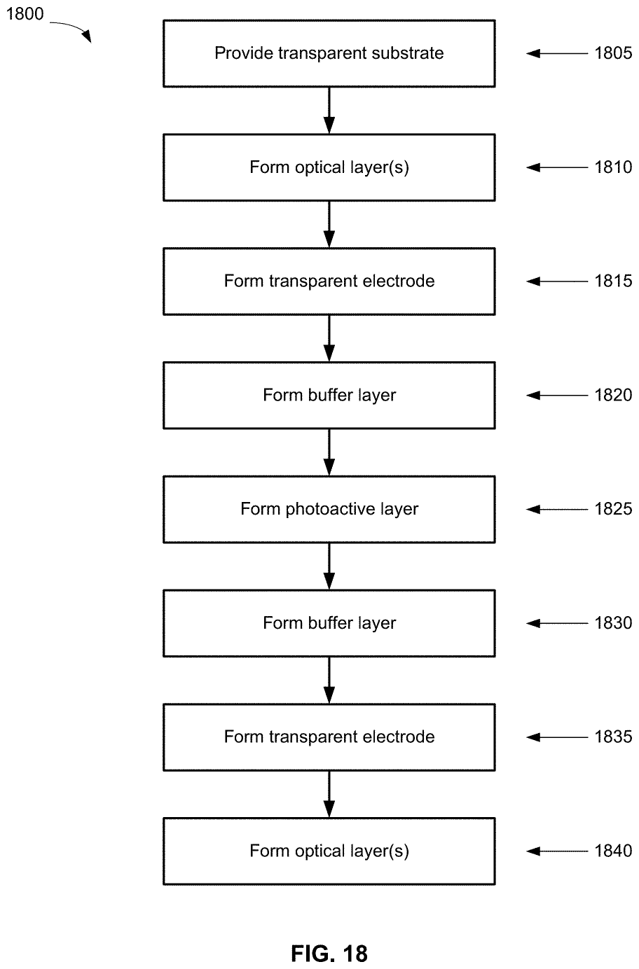

FIG. 18 is a simplified flow chart 1800 illustrating an example of a method for manufacturing a color-neutral TPV device according to certain embodiments. Flow chart 1800 may begin at block 1805, where a transparent substrate is provided. It will be appreciated that useful transparent substrates may include visibly transparent substrates, such as glass, plastic, quartz, and the like. Flexible and rigid substrates are useful with various embodiments. Optionally, the transparent substrate is provided with one or more optical layers applied on top and/or bottom surfaces.

At block 1810, one or more optical layers are optionally formed on or over the transparent substrate, such as on top and/or bottom surfaces of the transparent substrate. Optionally, the one or more optical layers are formed on other materials, such as an intervening layer or material, such as a transparent conductor. Optionally, the one or more optical layers are positioned adjacent to and/or in contact with the visibly transparent substrate. It will be appreciated that the formation of the optical layers is optional, and some embodiments may not include optical layers adjacent to and/or in contact with the transparent substrate. Optical layers may be formed using a variety of methods including, but not limited to, one or more chemical deposition methods, such as plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. It will be appreciated that useful optical layers include visibly transparent optical layers. Useful optical layers include those that provide one or more optical properties including, for example, antireflection properties, wavelength selective reflection or distributed Bragg reflection properties, index matching properties, encapsulation, or the like. Useful optical layers may optionally include optical layers that are transparent to ultraviolet and/or near-infrared light. Depending on the configuration, however, some optical layers may optionally provide passive infrared and/or ultraviolet absorption. Optionally, an optical layer may include a visibly absorbing material described herein.

At block 1815, a transparent electrode is formed. As described above, the transparent electrode may include an indium tin oxide thin film or other transparent conducting film, such as thin metal films (e.g., Ag, Cu, etc.), multilayer stacks comprising thin metal films (e.g., Ag, Cu, etc.) and dielectric materials, or conductive organic materials (e.g., conducting polymers, etc.). It will be appreciated that transparent electrodes include visibly transparent electrodes. Transparent electrodes may be formed using one or more deposition processes, including vacuum deposition techniques, such as atomic layer deposition, chemical vapor deposition, physical vapor deposition, thermal evaporation, sputter deposition, epitaxy, and the like. Solution based deposition techniques, such as spin-coating, may also be used in some cases. In addition, transparent electrodes may be patterned by way of microfabrication techniques, such as lithography, lift off, etching, and the like.

At block 1820, one or more buffer layers are optionally formed, such as on the transparent electrode. Buffer layers may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. It will be appreciated that useful buffer layers include visibly transparent buffer layers. Useful buffer layers include those that function as electron transport layers, electron blocking layers, hole transport layers, hole blocking layers, optical spacers, physical buffer layers, charge recombination layers, or charge generation layers. In some embodiments, a buffer layer may optionally include a visibly transparent photoactive compound described herein.

At block 1825, one or more photoactive layers are formed, such as on a buffer layer or on a transparent electrode. As described above, photoactive layers may include electron acceptor layers and electron donor layers or co-deposited layers of electron donors and acceptors (e.g., UE-D-100:C₆₀). Useful photoactive layers include those comprising the visibly transparent photoactive compounds described herein. As described above, in some embodiments, the photoactive layers may also include visibly absorbing materials (e.g., PTCBI or C₇₀) that may have transmission spectra complementary to the transmission spectra of the visibly transparent photoactive compounds in the visible band to achieve a neutral transmitted color. Photoactive layers may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition.

In some examples, visibly transparent photoactive compounds useful for photoactive layers may be deposited using a vacuum deposition technique, such as thermal evaporation. Vacuum deposition may take place in a vacuum chamber, such as at pressures of between about 10⁻⁵ Torr and about 10⁻⁸ Torr. In one example, vacuum deposition may take place at a pressure of about 10⁻⁷ Torr. As noted above, various deposition techniques may be applied. In some embodiments, thermal evaporation is used. Thermal evaporation may include heating a source of the material (i.e., the visibly transparent photoactive compound) to be deposited to a temperature of between 200° C. and 1800° C. The temperature of the source of material may be selected so as to achieve a thin film growth rate of between about 0.01 nm/s and about 1 nm/s. For example, a thin film growth rate of 0.1 nm/s may be used. These growth rates are useful to generate thin films having thicknesses of between about 1 nm and 1800 nm over the course of minutes to hours. It will be appreciated that various properties (e.g., the molecular weight, volatility, thermal stability) of the material being deposited may dictate or influence the source temperature or maximum useful source temperature. For example, a thermal decomposition temperature of the material being deposited may limit the maximum temperature of the source. As another example, a material being deposited that is highly volatile may require a lower source temperature to achieve a target deposition rate as compared to a material that is less volatile, where a higher source temperature may be needed to achieve the target deposition rate. As the material being deposited is evaporated from the source, it may be deposited on a surface (e.g., substrate, optical layer, transparent electrode, buffer layer, etc.) at a lower temperature. For example the surface may have a temperature from about 10° C. to about 100° C. In some cases, the temperature of the surface may be actively controlled. In some cases, the temperature of the surface may not be actively controlled.

At block 1830, one or more buffer layers are optionally formed, such as on the photoactive layer. The buffer layers formed at block 1830 may be formed similar to those formed at block 1820. It will be appreciated that blocks 1820, 1825, and 1830 may be repeated one or more times, such as to form a multilayer stack of materials including a photoactive layer and, optionally, various buffer layers.

At block 1835, a second transparent electrode is formed, such as on a buffer layer or on a photoactive layer. Second transparent electrode may be formed using techniques applicable to the formation of the first transparent electrode at block 1815.

At block 1840, one or more additional optical layers are optionally formed, such as on the second transparent electrode. As described above with respect to FIGS. 11A, 11B, and 14-16, in some embodiments, the optical layer may include a visibly absorbing material (e.g., PTCBI) that may not contribute to the photocurrent but may have a transmission spectrum complementary to the transmission spectrum of the visibly transparent photoactive materials in the visible band to achieve a neutral transmitted color.

It should be appreciated that the specific steps illustrated in FIG. 18 provide a particular method of making a visibly transparent photovoltaic device according to various embodiments of the present invention. Other sequences of steps may also be performed according to alternative embodiments. For example, alternative embodiments of the present invention may perform the steps outlined above in a different order. Moreover, the individual steps illustrated in FIG. 18 may include multiple sub-steps that may be performed in various sequences as appropriate to the individual step. Furthermore, additional steps may be added or removed depending on the particular applications. It will be appreciated that many variations, modifications, and alternatives may be used.

The method shown by FIG. 18 may optionally be extended to a method for generating electrical energy. For example, a method for generating electrical energy may comprise providing a visibly transparent photovoltaic device, such as by making a visibly transparent photovoltaic device according to the method. Methods for generating electrical energy may further comprise exposing the visibly transparent photovoltaic device to visible, ultraviolet and/or near-infrared light to drive the formation and separation of electron-hole pairs, as described above, for example, for generation of electrical energy. The visibly transparent photovoltaic device may include the visibly transparent photoactive compounds described herein as photoactive materials, buffer materials, and/or optical layers.

According to embodiments of the present invention, one or more of the device structures discussed herein and illustrated in the figures can utilize various types of buffer layers between the photoactive layers and the transparent electrodes. These buffer layers may be used to provide optical, electronic, or morphological benefits leading to improved solar cell performance, aesthetics, fabrication, and/or stability.

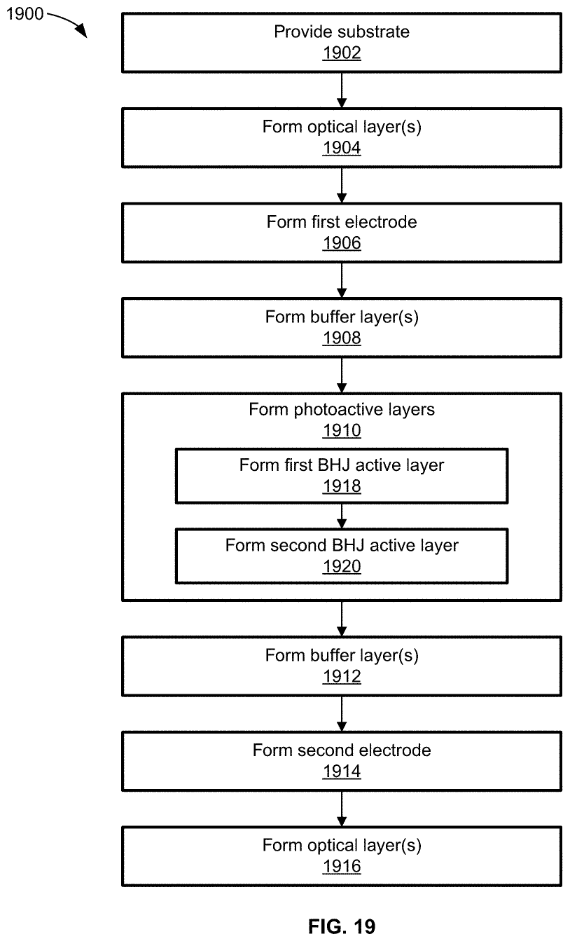

FIG. 19 illustrates a method 1900 for making a photovoltaic device, such as visibly transparent photovoltaic device 100, device structures 600, 800, 1000, 1200, 1400, 1700, or any combinations thereof. In various embodiments, the photovoltaic device may be visibly transparent or may be opaque. For example, any of the components described in reference to method 1900 as being visibly transparent may, in some embodiments, be opaque. Method 1900 may include additional or fewer steps than is illustrated in FIG. 19. Furthermore, one or more steps of method 1900 may be performed in a different order than is illustrated in FIG. 19.

Method 1900 begins at block 1902, where a substrate is provided, such as, e.g., a transparent substrate. It will be appreciated that useful transparent substrates include visibly transparent substrates, such as glass, plastic, quartz, and the like. Flexible and rigid substrates are useful with various embodiments. Optionally, the transparent substrate is provided with one or more optical layers preformed on top and/or bottom surfaces.

At block 1904, one or more optical layers are optionally formed on or over the transparent substrate, such as on top and/or bottom surfaces of the transparent substrate. Optionally, the one or more optical layers are formed on other materials, such as an intervening layer or material, such as a transparent conductor. Optionally, the one or more optical layers are positioned adjacent to and/or in contact with the visibly transparent substrate. It will be appreciated that formation of optical layers is optional, and some embodiments may not include optical layers adjacent to and/or in contact with the transparent substrate. Optical layers may be formed using a variety of methods including, but not limited to, one or more chemical deposition methods, such as plating, chemical solution deposition, spin coating, dip coating, slot-die coating, blade coating, spray coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. It will be appreciated that useful optical layers include visibly transparent optical layers. Useful optical layers include those that provide one or more optical properties including, for example, antireflection properties, wavelength selective reflection or distributed Bragg reflection properties, index matching properties, encapsulation, or the like. Useful optical layers may optionally include optical layers that are transparent to ultraviolet and/or near-infrared light. Depending on the configuration, however, some optical layers may optionally provide passive infrared and/or ultraviolet absorption. Optionally, an optical layer may include a visibly transparent photoactive compound described herein.

At block 1906, a first (e.g., bottom) electrode is formed, such as, e.g., a first transparent electrode. As described above, the transparent electrode may correspond to an ITO thin film or other transparent conducting film, such as thin metal films (e.g., Ag, Cu, etc.), multilayer stacks comprising thin metal films (e.g., Ag, Cu, etc.) and dielectric materials, or conductive organic materials (e.g., conducting polymers, etc.). It will be appreciated that transparent electrodes include visibly transparent electrodes. Transparent electrodes may be formed using one or more deposition processes, including vacuum deposition techniques, such as atomic layer deposition, chemical vapor deposition, physical vapor deposition, thermal evaporation, sputter deposition, epitaxy, etc. Solution based deposition techniques, such as spin-coating, may also be used in some cases. In addition, transparent electrodes may be patterned by way of microfabrication techniques, such as lithography, lift off, etching, etc.

At block 1908, one or more buffer layers are optionally formed, such as on the transparent electrode. Buffer layers may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. It will be appreciated that useful buffer layers include visibly transparent buffer layers. Useful buffer layers include those that function as electron transport layers, electron blocking layers, hole transport layers, hole blocking layers, optical spacers, physical buffer layers, charge recombination layers, or charge generation layers. In some cases, the disclosed visibly transparent photoactive compounds may be useful as a buffer layer material. For example, a buffer layer may optionally include a visibly transparent photoactive compound described herein.

At block 1910, one or more photoactive layers are formed, such as on a buffer layer or on a transparent electrode. As described above, the photoactive layers may comprise electron acceptor layers and electron donor layers or co-deposited layers of electron donors and acceptors. Photoactive layers may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition.

In some embodiments, block 1910 may include forming one or more bulk heterojunction (BHJ) active layers. For example, at block 1918, a first BHJ active layer is formed. In some embodiments, the first BHJ active layer is formed on the first transparent electrode formed at block 1906 or on the buffer layer formed at block 1908. The first BHJ active layer may comprise a blend (i.e., first blend) of an electron donor material (i.e., first electron donor material) and an electron acceptor material (i.e., first electron acceptor material). The first BHJ active layer may have a HOMO energy level (i.e., first HOMO energy level) that is characterized by (e.g., equal to) a HOMO energy level of the first electron donor material, and a LUMO energy level (i.e., first LUMO energy level) that is characterized by (e.g., equal to) a LUMO energy level of the first electron acceptor material.

The first BHJ active layer may be a binary, ternary, quaternary, or a higher-order blend of electron donor materials (including the first electron donor material) and electron acceptor materials (including the first electron acceptor material). The first BHJ active layer may be coated by an exciton-blocking layer, a hole-blocking layer, or an electron-blocking layer. In some embodiments, an exciton-blocking layer, a hole-blocking layer, or an electron-blocking layer is disposed (e.g., deposited) between the first BHJ active layer and the first transparent electrode.

As another example, at block 1920, a second BHJ active layer is formed. In some embodiments, the second BHJ active layer is formed on the first BHJ active layer formed at block 1918. The second BHJ active layer may comprise a blend (i.e., second blend) of an electron donor material (i.e., second electron donor material) and an electron acceptor material (i.e., second electron acceptor material). The second BHJ active layer may have a HOMO energy level (i.e., second HOMO energy level) that is characterized by (e.g., equal to) a HOMO energy level of the second electron donor material, and a LUMO energy level (i.e., second LUMO energy level) that is characterized by (e.g., equal to) a LUMO energy level of the second electron acceptor material.

The second BHJ active layer may be a binary, ternary, quaternary, or a higher-order blend of electron donor materials (including the second electron donor material) and electron acceptor materials (including the second electron acceptor material). The second BHJ active layer may be coated by an exciton-blocking layer, a hole-blocking layer, or an electron-blocking layer. In some embodiments, an exciton-blocking layer, a hole-blocking layer, or an electron-blocking layer is disposed between the second BHJ active layer and a second transparent electrode.

In some embodiments, the first BHJ active layer may have a distinct electron donor material from the second BHJ active layer (e.g., the first electron donor material may be different than the second electron donor material). In some embodiments, the first BHJ active layer may share an electron donor material with the second BHJ active layer (e.g., the first electron donor material may be the same as the second electron donor material). In some embodiments, the first BHJ active layer may have a distinct electron acceptor material from the second BHJ active layer (e.g., the first electron acceptor material may be different than the second electron acceptor material). In some embodiments, the first BHJ active layer may share an electron acceptor material with the second BHJ active layer (e.g., the first electron acceptor material may be the same as the second electron acceptor material).

In various embodiments, the first LUMO energy level and the second LUMO energy level may be within 100 meV, 200 meV, 300 meV, 400 meV, or 500 meV of each other. In various embodiments, the first HOMO energy level and the second HOMO energy level may be within 100 meV, 200 meV, 300 meV, 400 meV, or 500 meV of each other.

In some embodiments, the first BHJ active layer may have one or more peak absorption wavelengths, which are wavelengths where the absorption of radiation by the first BHJ active layer exhibits a peak. In some embodiments, the second BHJ active layer may have one or more peak absorption wavelengths, which are wavelengths where the absorption of radiation by the second BHJ active layer exhibits a peak. In some embodiments, a peak absorption wavelength of the first BHJ active layer is at least partially complementary to a peak absorption wavelength of the second BHJ active layer. In such embodiments, the peak absorption wavelength of the first BHJ active layer is offset from the peak absorption wavelength of the second BHJ active layer by at least a wavelength offset amount so as to provide broader spectral coverage. In various embodiments, the wavelength offset amount may be 50 nm, 100 nm, 150 nm, 200 nm, 250 nm, 300 nm, 350 nm, or any value there between.

At block 1912, one or more buffer layers are optionally formed, such as on the photoactive layer. The buffer layers formed at block 1912 may be formed similar to those formed at block 1908.

At block 1914, a second (e.g., top) electrode is formed, such as, e.g., a second transparent electrode. The second transparent electrode may be formed on a buffer layer or on a photoactive layer. The second transparent electrode may be formed using techniques applicable to formation of first transparent electrode at block 515.

At block 1916, one or more additional optical layers are optionally formed, such as on the second transparent electrode.

Method 1900 may optionally be extended to correspond to a method for generating electrical energy. For example, a method for generating electrical energy may comprise providing a visibly transparent photovoltaic device, such as by making a visibly transparent photovoltaic device according to method 1900. Methods for generating electrical energy may further comprise exposing the visibly transparent photovoltaic device to visible, ultraviolet and/or near-infrared light to drive the formation and separation of electron-hole pairs, for example, for generation of electrical energy. The visibly transparent photovoltaic device may include the visibly transparent photoactive compounds described herein as photoactive materials, buffer materials, and/or optical layers.

All references throughout this disclosure, for example patent documents including issued or granted patents or equivalents; patent application publications; and non-patent literature documents or other source material; are hereby incorporated by reference herein in their entireties, as though individually incorporated by reference.

All patents and publications mentioned in this disclosure are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a compound is claimed, it should be understood that compounds known in the prior art, including certain compounds disclosed in the references disclosed herein (particularly in referenced patent documents), are not intended to be included in the claim.

When a group of substituents is disclosed herein, it is understood that all individual members of those groups and all subgroups and classes that can be formed using the substituents are disclosed separately. When a Markush group or other grouping is used herein, all individual members of the group and all combinations and sub-combinations possible of the group are intended to be individually included in the disclosure. As used herein, “and/or” means that one, all, or any combination of items in a list separated by “and/or” are included in the list; for example “1, 2 and/or 3” is equivalent to “‘1’ or ‘2’ or ‘3’ or ‘1 and 2’ or ‘1 and 3’ or ‘2 and 3’ or ‘1, 2 and 3’”.

Every formulation or combination of components described or exemplified can be used to practice the invention, unless otherwise stated. Specific names of materials are intended to be exemplary, as it is known that one of skill in the art can name the same material differently. It will be appreciated that methods, device elements, starting materials, and synthetic methods other than those specifically exemplified can be employed in the practice of the invention without resort to undue experimentation. All art-known functional equivalents, of any such methods, device elements, starting materials, and synthetic methods are intended to be included in this invention. Whenever a range is given in the specification, for example, a temperature range, a time range, or a composition range, all intermediate ranges and subranges, as well as all individual values included in the ranges given are intended to be included in the disclosure.

As used herein, “comprising” is synonymous with “including,” “containing,” “having,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

As used herein, the terms “a,” “an,” “the,” and similar referents in the context of describing the disclosed embodiments (especially in the context of the following claims) are to be construed to cover both the singular and the plural, unless otherwise indicated herein or clearly contradicted by context. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein and each separate value is incorporated into the specification as if it were individually recited herein. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is intended to be understood within the context as used in general to present that an item, term, and the like, may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Abbreviations for some materials (e.g., some NIR or UV-absorbing materials) that may be utilized in the present specification include:
TPBi: 2,2′,2″-(1,3,5-Benzinetriyl)-tris(1-phenyl-1-H-benzimidazole)
HAT-CN: Dipyrazino[2,3-f:2′,3′-h]quinoxaline-2,3,6,7,10,11-hexacarbonitrile
PTCBI: Bisbenzimidazo[2,1-a:1′,2-b′]anthra[2,1,9-def:6,5,10-d′e′f′]diisoquinoline-10,21-dione
ITO: Indium tin oxide

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered within the scope of this invention as defined by the appended claims.

What is claimed is:

1. A visibly transparent photovoltaic device comprising:
a visibly transparent substrate;
a first visibly transparent electrode coupled to the visibly transparent substrate;
a second visibly transparent electrode;
a visibly transparent photoactive layer between the first visibly transparent electrode and the second visibly transparent electrode, the visibly transparent photoactive layer configured to convert at least one of near-infrared (NIR) light or ultraviolet (UV) light into photocurrent and characterized by an absorption spectrum with a peak in the NIR or UV spectrum; and
a visibly absorbing material characterized by a second absorption spectrum with a second peak in the visible spectrum, wherein the second absorption spectrum is complementary to the absorption spectrum.

2. The visibly transparent photovoltaic device of claim 1, wherein the visibly transparent photovoltaic device is characterized by a flat transmission profile across the visible spectrum, having an absolute variation in transmission percentage of less than 30% between the wavelengths of 450 nm and 650 nm.

3. The visibly transparent photovoltaic device of claim 2, wherein the absolute variation in transmission percentage is less than 10%.

4. The visibly transparent photovoltaic device of claim 1, wherein the visibly transparent photovoltaic device is characterized by transmitted a* and b* values between −10 and 10 in International Commission on Illumination (CIE) L*a*b* (CIELAB) color space.

5. The visibly transparent photovoltaic device of claim 4, wherein the visibly transparent photovoltaic device is characterized by the transmitted a* and b* values between −5 and 5 in the CIELAB color space.

6. The visibly transparent photovoltaic device of claim 1, wherein the visibly transparent photovoltaic device is characterized by negative transmitted a* and negative transmitted b* values in the International Commission on Illumination (CIE) L*a*b* (CIELAB) color space.

7. The visibly transparent photovoltaic device of claim 1, wherein the visibly transparent photovoltaic device is characterized by an average visible transmission (AVT) greater than 40%.

8. The visibly transparent photovoltaic device of claim 1, wherein the visibly transparent photoactive layer includes a donor material and an acceptor material.

9. The visibly transparent photovoltaic device of claim 1, wherein the visibly absorbing material is included in the visibly transparent photoactive layer.

10. The visibly transparent photovoltaic device of claim 1, wherein the visibly absorbing material is included in an optical layer of the visibly transparent photovoltaic device.

11. The visibly transparent photovoltaic device of claim 1, wherein the visibly absorbing material is blended with the photoactive layers in a ternary or quaternary blend.

12. The visibly transparent photovoltaic device of claim 1, wherein the visibly absorbing material is disposed between the first electrode and the photoactive layers.

13. The visibly transparent photovoltaic device of claim 1, wherein the visibly absorbing material is disposed between the photoactive layers and the second electrode.

14. The visibly transparent photovoltaic device of claim 1, wherein the visibly absorbing material is disposed above the second electrode.

15. The visibly transparent photovoltaic device of claim 1, further comprising a second visibly absorbing material characterized by a third absorption spectrum with a third peak in the visible spectrum, wherein the third absorption spectrum is complementary to the absorption spectrum and the second absorption spectrum, wherein the first visibly absorbing material is disposed between the first electrode and the photoactive layers and the second visibly absorbing material is disposed between the photoactive layers and the second electrode.

16. The visibly transparent photovoltaic device of claim 1, further comprising a second visibly absorbing material characterized by a third absorption spectrum with a third peak in the visible spectrum, wherein the third absorption spectrum is complementary to the absorption spectrum and the second absorption spectrum, wherein the first visibly absorbing material is disposed between the first electrode and the second electrode and the second visibly absorbing material is disposed above the second electrode.

17. The visibly transparent photovoltaic device of claim 1, wherein the visibly absorbing material is included in a photoactive binary, ternary, or quaternary blend disposed between the first visibly transparent electrode and the second visibly transparent electrode.

18. A method of manufacturing a visibly transparent photovoltaic device, the method comprising:
providing a visibly transparent substrate;
forming a first visibly transparent electrode coupled to the visibly transparent substrate;
forming a second visibly transparent electrode;
forming a visibly transparent photoactive layer between the first visibly transparent electrode and the second visibly transparent electrode, the visibly transparent photoactive layer configured to convert at least one of near-infrared (NIR) light or ultraviolet (UV) light into photocurrent and characterized by an absorption spectrum with a peak in the NIR or UV spectrum; and
incorporating a visibly absorbing material characterized by a second absorption spectrum with a second peak in the visible spectrum, wherein the second absorption spectrum is complementary to the absorption spectrum.

19. The method of claim 18, wherein the visibly transparent photovoltaic device is characterized by a flat transmission profile across the visible spectrum, having an absolute variation in transmission percentage of less than 30% between the wavelengths of 450 nm and 650 nm.
